(19) United States
(12) Patent Application Publication
(10) Pub. No.: US 2026/0040831 A1
(43) Pub. Date: Feb. 5, 2026

(54) MAGNETIC MEMORY DEVICE INCLUDING A MAGNETIC TUNNEL JUNCTION AND A METHOD OF MANUFACTURING THE MAGNETIC MEMORY DEVICE

(71) Applicant: SAMSUNG ELECTRONICS CO., LTD., SUWON-SI (KR)

(72) Inventors: CHAE LYOUNG KIM, Suwon-si (KR); JINMYOUNG LEE, Suwon-si (KR)

(21) Appl. No.: 19/175,314

(22) Filed: Apr. 10, 2025

(30) Foreign Application Priority Data
Jul. 31, 2024 (KR) 10-2024-0101596

(51) Int. Cl. H10N 50/10; H10B 61/00; H10D 30/00; H10D 30/43; H10D 62/10; H10D 64/23

(52) U.S. Cl. CPC H10N 50/10; H10B 61/22; H10D 30/43; H10D 30/502; H10D 62/121; H10D 64/251

(57) ABSTRACT

A magnetic memory device includes: a substrate having upper and lower surfaces; a first active region on the upper surface of the substrate, and including a lower channel pattern and a lower source/drain pattern connected to the lower channel pattern; a second active region on the first active region, and including an upper channel pattern and an upper source/drain pattern connected to the upper channel pattern; an interlayer insulating layer covering the lower and upper source/drain patterns; a first active contact on the upper source/drain pattern; an upper insulating layer disposed on the interlayer insulating layer; a first magnetic tunnel junction pattern in the upper insulating layer, and connected to the first active contact; a backside wiring layer on the lower surface of the substrate; a second magnetic tunnel junction pattern in the backside wiring layer; and a second active contact on the lower source/drain pattern.

### CROSS-REFERENCE TO RELATED APPLICATION

This U.S. non-provisional patent application claims priority under 35 U.S.C. § 119 to Korean Patent Application No. 10-2024-0101596 filed on Jul. 31, 2024, in the Korean Intellectual Property Office, the disclosure of which is incorporated by reference herein in its entirety.

### TECHNICAL FIELD

The present inventive concept relates to a magnetic memory device, and more specifically, to a magnetic memory device including a magnetic tunnel junction, and a method of manufacturing the same.

### DISCUSSION OF THE RELATED ART

As demand for electronic devices with high-speed and/or low power consumption electronic devices increases, demand for semiconductor memory devices that operate with high-speed performance and/or at low-voltage also increase. Magnetic memory devices have been under development as semiconductor memory devices that are capable of satisfying these demands. The magnetic memory devices may emerge as next-generation semiconductor memory devices because of their high-speed and/or non-volatile characteristics.

In general, a magnetic memory device may include a magnetic tunnel junction MTJ pattern. A magnetic tunnel junction pattern may include two magnetic layers and an insulating layer disposed between the two magnetic layers. A resistance associated with the magnetic tunnel junction pattern may be changed based at least in part upon magnetization directions of the two magnetic layers. For example, when the magnetization directions of the two magnetic layers are anti-parallel to each other, the magnetic tunnel junction pattern may have a high resistance. When the magnetization directions of the two magnetic layers are parallel to each other, the magnetic tunnel junction pattern may have a low resistance. A magnetic memory device may read/write data by using a difference between these resistance values of the magnetic tunnel junction pattern.

Data required to manage the magnetic memory device may be stored and managed in one time programmable (OTP) cells. The OTP cells may be formed by applying a high voltage to a general MTJ element to cause a breakdown, and it is necessary to prevent other MTJ elements from being affected by the high voltage. Therefore, it is common to place normal cells, where user data is stored, and OTP cells in separate memory cell arrays. However, as the area of the memory cell array increases, the area of the write driver increases, and accordingly manufacturing cost increases as well.

### SUMMARY

According to embodiments of the present inventive concept, a magnetic memory device includes: a substrate having upper and lower surfaces facing each other; a first active region disposed on the upper surface of the substrate, wherein the first active region includes a lower channel pattern and a lower source/drain pattern connected to the lower channel pattern; a second active region stacked on the first active region, wherein the second active region includes an upper channel pattern and an upper source/drain pattern connected to the upper channel pattern; an interlayer insulating layer covering the lower and upper source/drain patterns; a first active contact extending from an upper surface of the interlayer insulating layer to be disposed on the upper source/drain pattern; an upper insulating layer disposed on the interlayer insulating layer; a first magnetic tunnel junction pattern disposed in the upper insulating layer, wherein the first magnetic tunnel junction pattern is connected to the first active contact through an interlayer wiring; a backside wiring layer disposed on the lower surface of the substrate; a second magnetic tunnel junction pattern disposed in the backside wiring layer; and a second active contact extending from the lower surface of the substrate to be disposed on the lower source/drain pattern, wherein the second active contact is connected to the second magnetic tunnel junction pattern.

According to embodiments of the present inventive concept, a magnetic memory device includes: a substrate having first and second surfaces facing each other; a first active region disposed on the first surface of the substrate, wherein the first active region includes a lower channel pattern and a lower source/drain pattern connected to the lower channel pattern; a first interlayer insulating layer covering the lower source/drain pattern; a first active contact extending from an upper surface of the first interlayer insulating layer into an interior of the lower source/drain pattern; an upper insulating layer disposed on the first interlayer insulating layer; a first magnetic tunnel junction pattern disposed in the upper insulating layer, wherein the first magnetic tunnel junction pattern is connected to the first active contact through an interlayer wiring; a backside wiring layer disposed on the lower surface of the substrate; a second magnetic tunnel junction pattern disposed in the backside wiring layer; and a second active contact extending from the lower surface of the substrate into the interior of the lower source/drain pattern and being connected to the second magnetic tunnel junction pattern, wherein each of the first and second magnetic tunnel junction patterns includes a pinned magnetic pattern, a free magnetic pattern, and a tunnel barrier pattern therebetween, and wherein the tunnel barrier pattern of the first magnetic tunnel junction pattern is insulated-broken and has an irreversible resistance state.

According to embodiments of the present inventive concept, a magnetic memory device includes: a magnetic memory device having a substrate having upper and lower surfaces facing each other, wherein the substrate includes an active pattern; a first active region disposed on the active pattern, wherein the first active region includes a lower channel pattern and a lower source/drain pattern connected to the lower channel pattern; a second active region stacked on the first active region, wherein the second active region includes an upper channel pattern and an upper source/drain pattern connected to the upper channel pattern; a gate electrode disposed on the lower channel pattern and the upper channel pattern, wherein the gate electrode extends in a first direction; an interlayer insulating layer covering the lower and upper source/drain patterns; a first active contact extending from an upper surface of the interlayer insulating layer into an interior of the upper source/drain pattern; an upper insulating layer disposed on the interlayer insulating layer; a wiring insulating layer disposed on the upper insulating layer; a first wiring disposed on the wiring insulating layer; a first magnetic tunnel junction pattern in the upper insulating layer, wherein the first magnetic tunnel junction pattern is connected to the first active contact through interlayer wiring and upper vias, and connected to the first wiring through upper wiring and upper connection line in the wiring insulating layer; a backside wiring layer disposed on the lower surface of the substrate; a second magnetic tunnel junction pattern and a lower wiring disposed in the backside wiring layer, wherein the second magnetic tunnel junction pattern is disposed between the substrate and the lower wiring; a second active contact extends from the lower surface of the substrate into the lower source/drain pattern and connected to the second magnetic tunnel junction pattern; a lower via connecting the lower wiring and the second magnetic tunnel junction pattern to each other; and a through-contact plug penetrating the upper insulating layer, the interlayer insulating layer, and the substrate, and penetrating a portion of the backside wiring layer to connect the upper wiring and the lower wiring to each other.

### BRIEF DESCRIPTION OF THE DRAWINGS

The above and other aspects of the present inventive concept will become readily apparent by reference to the following detailed description when considered in conjunction with the accompanying drawings wherein:

FIG. 1 is a circuit diagram illustrating a unit memory cell of a semiconductor device according to embodiments of the present inventive concept.

FIGS. 2A and 2B are cross-sectional views illustrating a magnetic tunnel junction pattern constituting the memory cell of FIG. 1.

FIG. 3 is a plan view of a magnetic memory device according to some embodiments of the present inventive concept.

FIGS. 4A, 4B, 4C and 4D are cross-sectional views along lines A-A′, B-B′, C-C′, and D-D′ of FIG. 3, respectively.

FIGS. 5A, 5B, 6A, 6B, 7A, 7B, 8A, 8B, 9A, 9B, 10A, 10B, 11A, 11B, 12A, 12B, 13A, 13B, 13C, 13D, 14A, 14B, 15A, 15B, 15C, 15D, 16A, 16B, 16C, and 16D are cross-sectional views for illustrating a method of manufacturing a magnetic memory device according to an embodiment of the present inventive concept.

FIGS. 17A, 17B, 17C and 17D are cross-sectional views of a magnetic memory device according to embodiments of the present inventive concept, and are cross-sectional views taken along lines A-A′, B-B′, C-C′, and D-D′ of FIG. 3, respectively.

FIGS. 18A, 18B, 18C, and 18D are cross-sectional views of a magnetic memory device according to embodiments of the present inventive concept, and are cross-sectional views taken along lines A-A′, B-B′, C-C′, and D-D′ of FIG. 3, respectively.

FIG. 19 is a plan view of a magnetic memory device according to embodiments of the present inventive concept.

FIGS. 20A, 20B, 20C, and 20D are cross-sectional views of a magnetic memory device according to embodiments of the present inventive concept, and are cross-sectional views taken along lines A-A′, B-B′, C-C′, and D-D′ of FIG. 19, respectively.

FIGS. 21A, 21B, 21C, and 21D are cross-sectional views of a magnetic memory device according to embodiments of the present inventive concept, taken along lines A-A′, B-B′, C-C′, and D-D′ of FIG. 19, respectively.

FIGS. 22A, 22B, 22C, and 22D are cross-sectional views of a magnetic memory device according to embodiments of the present inventive concept, taken along lines A-A′, B-B′, C-C′, and D-D′ of FIG. 19, respectively.

FIG. 23 is a plan view of a magnetic memory device according to embodiments of the present inventive concept.

FIGS. 24A, 24B, 24C and 24D are cross-sectional views of a magnetic memory device according to embodiments of the present inventive concept, taken along lines A-A′, B-B′, C-C′, and D-D′ of FIG. 23, respectively.

### DETAILED DESCRIPTION

Hereinafter, the present inventive concept will be described in detail by describing embodiments of the present inventive concept with reference to the attached drawings.

Embodiments of the present inventive concept relate to a magnetic memory device that offers high integration and reduced wiring complexity. According to embodiments of the present inventive concept, the memory device may include vertically stacked active regions and magnetic tunnel junctions (MTJs) on both the front and back surfaces of the substrate. The MTJs may enable the device to perform as both a main memory cell and a one-time programmable (OTP) memory cell, addressing demands for compact, high-speed, and low-power semiconductor memory technologies.

According to embodiments of the present inventive concept, the device may include a first active region with a lower channel pattern and source/drain patterns on the substrate, and a second active region stacked above the first active region. The MTJs integrated into the layers on both the front and back surfaces of the substrate. This stacking allows for efficient use of space, increasing integration density and reducing the area for separate memory arrays. The MTJs use resistance changes based on magnetic orientation to read and write data, enabling non-volatile and high-speed memory operations.

A feature of the memory device is the use of MTJs in both reversible and irreversible states. For example, the MTJ functioning as an OTP cell is programmed into an irreversible “blown” state, where its resistance is permanently altered. The main memory MTJ retains its reversible resistance characteristics, enabling dynamic read/write operations. By strategically placing these MTJs on opposite sides of the substrate, the design may eliminate the need for separate OTP memory arrays, further reducing manufacturing costs and complexity.

Additionally, the memory device, according to embodiments of the present inventive concept, may include through-contact plugs and backside wiring to optimize electrical connectivity and reduce wiring complexity. This approach not only increases integration but also ensures efficient power distribution and signal routing. Overall, embodiments of the present inventive concept may provide a memory device that has increased integration and performance with reduce wiring complexity.

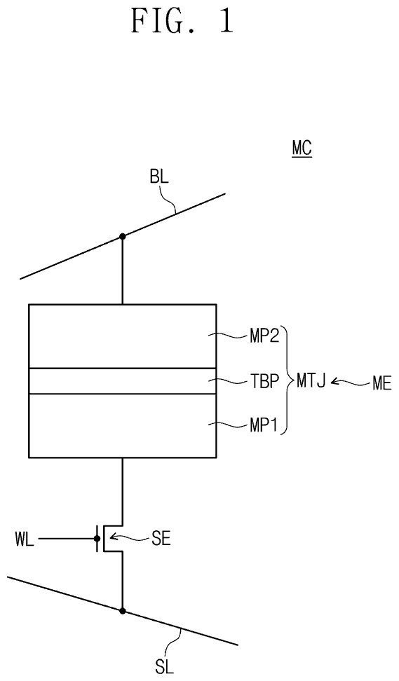

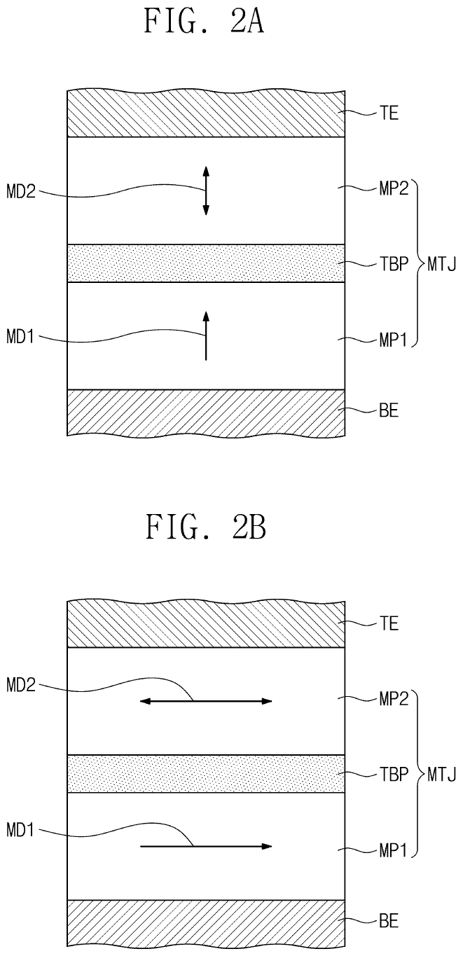

FIG. 1 is a circuit diagram illustrating a unit memory cell of a semiconductor device according to embodiments of the present inventive concept. FIGS. 2A and 2B are cross-sectional views illustrating a magnetic tunnel junction pattern constituting the memory cell of FIG. 1.

Referring to FIG. 1, a unit memory cell MC may include a memory element ME and a selection element SE. The memory element ME and the selection element SE may be electrically connected in series. The memory element ME may be connected between the selection element SE and a bit line BL. The selection element SE may be connected between the memory element ME and a source line SL, and controlled by a word line WL. The selection element SE may be a field effect transistor or a diode.

The memory element ME may include a magnetic tunnel junction MTJ pattern including magnetic patterns MP1 and MP2 that are spaced apart and a tunnel barrier pattern TBP between the magnetic patterns MP1 and MP2. One of the magnetic patterns MP1 or MP2 may be a reference layer whose magnetization direction is fixed regardless of an external magnetic field under a normal use environment. The other of the magnetic patterns MP1 and MP2 may be a free layer whose magnetization direction is freely changed by the external magnetic field. The magnetic tunnel junction MTJ may have an electrical resistance whose value is much greater when the magnetization directions of the reference and free layers are anti-parallel to each other relative to when the magnetization directions of the reference and free layers are parallel to each other. That is, the electrical resistance of the magnetic tunnel junction MTJ may be adjusted by changing the magnetization direction of the free layer. Accordingly, the memory element ME may store data in the unit memory cell MC by using the difference of the electrical resistance in accordance with the magnetization directions.

Referring to FIGS. 2A and 2B, the first magnetic pattern MP1 may be a reference layer having a magnetization direction MD1 fixed in one direction, and the second magnetic pattern MP2 may be a free layer having a changeable magnetization direction MD2 that is capable of being changed to be parallel or antiparallel to the magnetization direction MD1 of the first magnetic pattern MP1. FIGS. 2A and 2B each disclose that the second magnetic pattern MP2 is a free layer as an example, but the present inventive concept is not limited thereto. Unlike FIGS. 2A and 2B, the first magnetic pattern MP1 may be a free layer and the second magnetic pattern MP2 may be a reference layer.

Referring to FIG. 2A, for example, the magnetization directions MD1 and MD2 of the first magnetic pattern MP1 and the second magnetic pattern MP2 may be perpendicular to an interface between the tunnel barrier pattern TBP and the second magnetic pattern MP2. In this case, each of the first magnetic pattern MP1 and the second magnetic pattern MP2 may include at least one of an intrinsic perpendicular magnetic material or an extrinsic perpendicular magnetic material. The intrinsic perpendicular magnetic material may include a material that has perpendicular magnetic properties even though an external factor does not exist. For example, the intrinsic perpendicular magnetic material may include at least one of a perpendicular magnetic material (e.g., CoFeTb, CoFeGd, or CoFeDy), a perpendicular magnetic material having a L1₀ lattice structure, a CoPt alloy having a hexagonal close packed (HCP) lattice structure, and a perpendicular magnetic structure. For example, the perpendicular magnetic material having the L1₀ lattice structure may include at least one of FePt having the L1₀ lattice structure, FePd having the L1₀ lattice structure, CoPd having the L1₀ lattice structure, and CoPt having the L1₀ lattice structure. The perpendicular magnetic structure may include magnetic layers and non-magnetic layers that are alternately and repeatedly stacked. For example, the perpendicular magnetic structure may include at least one of (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n, where “n” denotes the number of stacked layers. The extrinsic perpendicular magnetic material may include a material that has intrinsic horizontal magnetic properties but has perpendicular magnetic properties by an external factor. For example, the extrinsic perpendicular magnetic material may have the perpendicular magnetic properties by magnetic anisotropy induced by a junction of the tunnel barrier pattern TBR and the first magnetic pattern MP1 (or the second magnetic pattern MP2). The extrinsic perpendicular magnetic material may include, for example, CoFeB.

Referring to FIG. 2B, as another example, the magnetization directions MD1 and MD2 of the first magnetic pattern MP1 and the second magnetic pattern MP2 may be parallel to an interface between the tunnel barrier pattern TBP and the second magnetic pattern MP2. In this case, each of the first magnetic pattern MP1 and the second magnetic pattern MP2 may include a ferromagnetic material. The first magnetic pattern MP1 may further include an antiferromagnetic material for fixing the magnetization direction of the ferromagnetic material in the first magnetic pattern MP1.

Each of the first magnetic pattern MP1 and the second magnetic pattern MP2 may include a Heusler alloy including Co. For example, the tunnel barrier pattern TBP may include at least one of a magnesium (Mg) oxide layer, a titanium (Ti) oxide layer, an aluminum (Al) oxide layer, a magnesium-zinc (Mg—Zn) oxide layer, or a magnesium-boron (Mg—B) oxide layer.

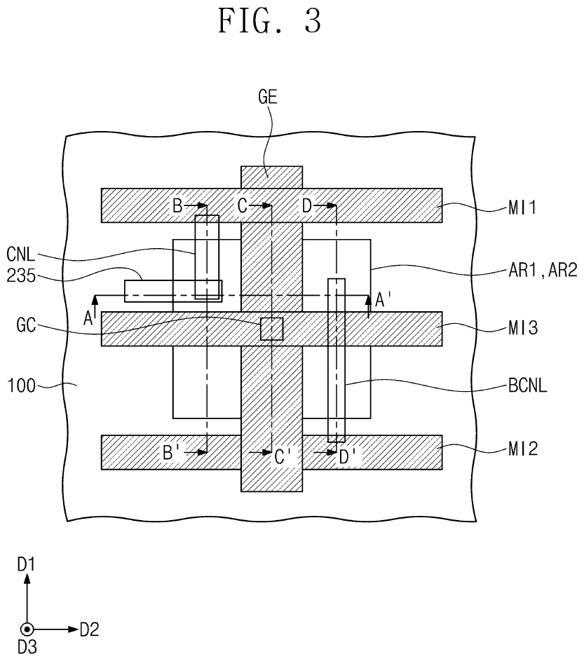

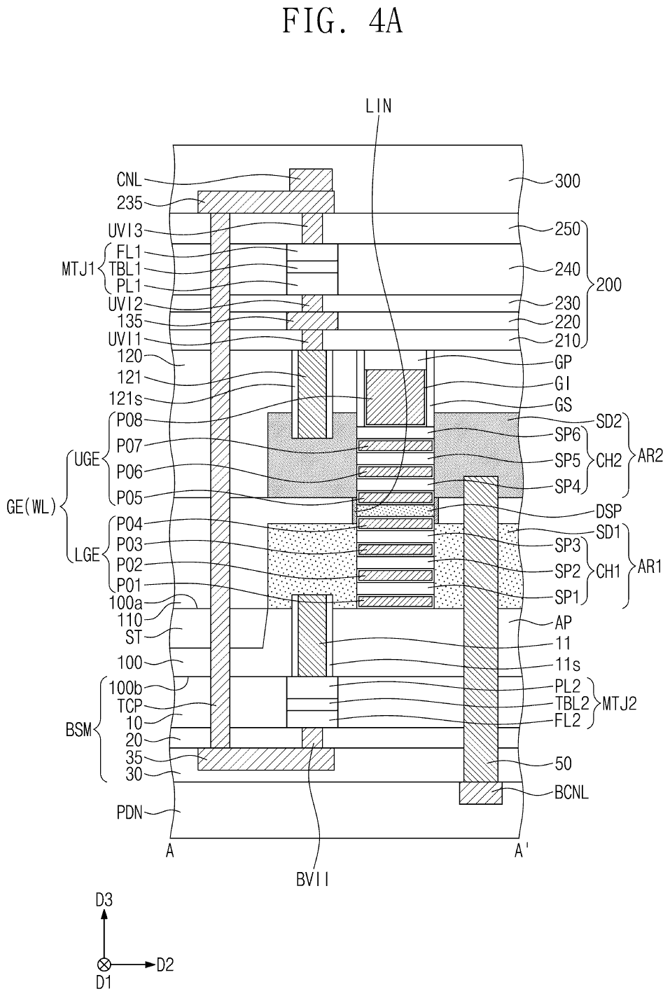

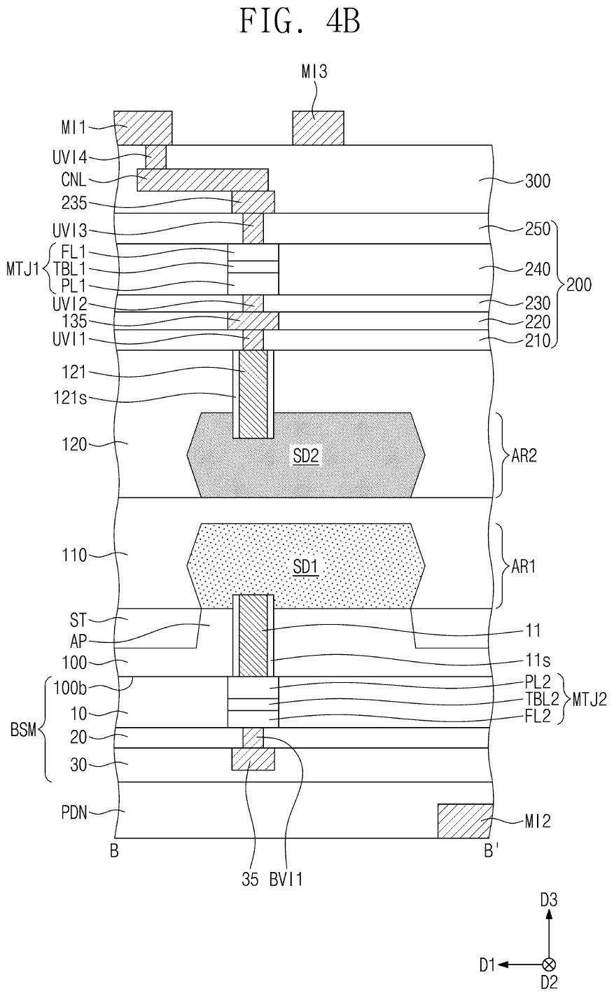

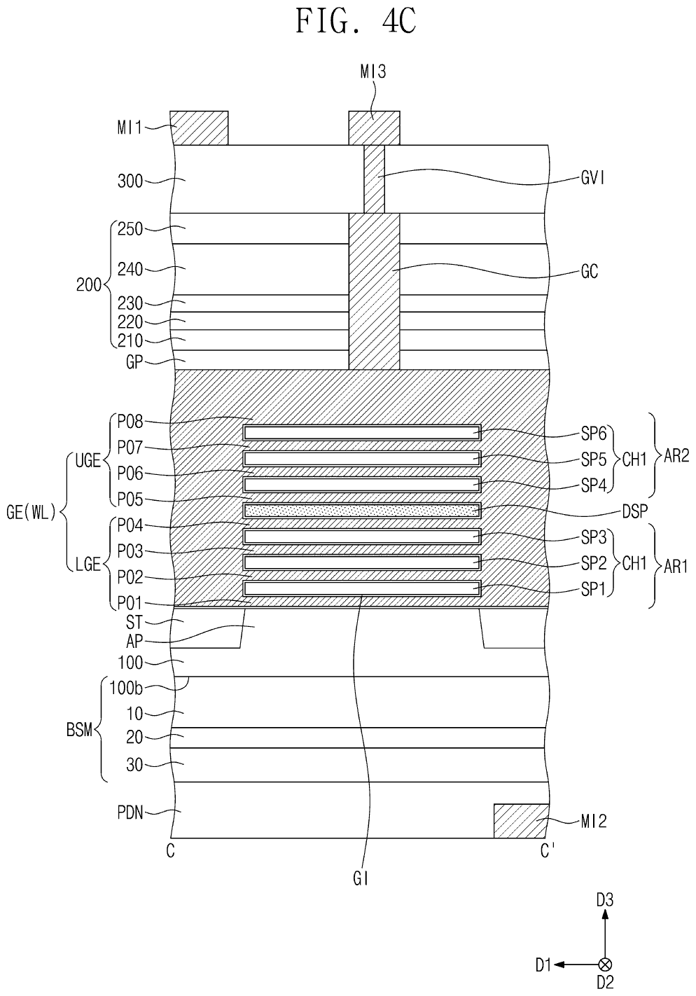

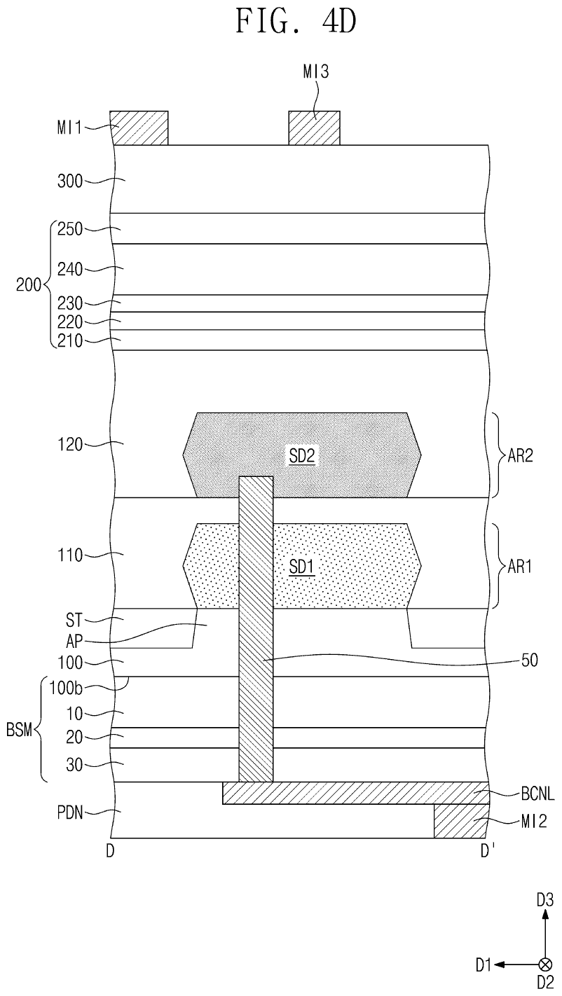

FIG. 3 is a plan view of a magnetic memory device according to embodiments of the present inventive concept. FIGS. 4A to 4D are cross-sectional views along lines A-A′, B-B′, C-C′, and D-D′ of FIG. 3, respectively.

Referring to FIGS. 3 and 4A to 4D, a substrate 100 having a front surface 100a and a back surface 100b facing each other in a third direction D3 may be provided. In this specification, the first direction D1 and the second direction D2 may be directions that are parallel to the front surface 100a of the substrate 100. The third direction D3 may be a direction that is perpendicular to the front surface 100a of the substrate 100. For example, the first direction D1, the second direction D2, and the third direction D3 may be directions that are orthogonal to each other. The third direction D3 may also be referred to as a vertical direction D3. The substrate 100 may be a semiconductor substrate (e.g., a silicon substrate, a germanium substrate, and/or a silicon-germanium substrate).

A first active region AR1 and a second active region AR2 are sequentially stacked on the substrate 100. One of the first or second active regions AR1 or AR2 may be a PMOSFET region, and the other of the first and second active regions AR1 and AR2 may be an NMOSFET region. The NMOSFET and PMOSFET of the first and second active regions AR1 and AR2 may be vertically stacked to form a three-dimensional stacked transistor.

A device isolation layer ST may be disposed on an upper portion of the substrate 100, and an active pattern AP may be defined by the device isolation layer ST. The active pattern AP may be a portion of the substrate 100 that protrudes vertically from a lower portion of the substrate 100. The first and second active regions AR1 and AR2 described above may be sequentially stacked on the active pattern AP. The device isolation layer ST may include a silicon oxide layer. An upper surface of the device isolation layer ST may be coplanar with or lower than an upper surface of the active pattern AP. The device isolation layer ST might not cover lower and upper channel patterns CH1 and CH2 to be described later.

The first active region AR1 may include a lower channel pattern CH1 and lower source/drain patterns SD1. The lower channel pattern CH1 may be interposed between lower source/drain patterns SD1. The lower source/drain patterns SD1 may be disposed on both sides of the lower channel pattern CH1 and may be spaced apart from each other in the second direction D2 by the lower channel pattern CH1. The lower channel pattern CH1 may connect the lower source/drain patterns SD1 to each other.

The lower channel pattern CH1 may include first to third semiconductor patterns SP1, SP2, and SP3 that are sequentially stacked. The first to third semiconductor patterns SP1, SP2, and SP3 may be spaced apart from each other in a vertical direction (e.g., in the third direction D3). For example, each of the first to third semiconductor patterns SP1, SP2, and SP3 may include silicon (Si), germanium (Ge), or silicon germanium (SiGe). For example, each of the first to third semiconductor patterns SP1, SP2, and SP3 may include crystalline silicon.

The lower source/drain patterns SD1 may be provided on the upper surface of the active pattern AP. The lower source/drain patterns SD1 may be epitaxial patterns formed by a selective epitaxial growth (SEG) process. For example, an upper surface of the lower source/drain patterns SD1 may be higher than an upper surface of the third semiconductor pattern SP3 of the lower channel pattern CH1.

The lower source/drain patterns SD1 may be doped with impurities to have a first conductivity type. The first conductivity type may be N type or P type. For example, the lower source/drain patterns SD1 may include at least one of silicon germanium (SiGe), silicon (Si), and/or silicon carbide (SiC). The lower source/drain patterns SD1 may be configured to provide tensile strain or compressive strain to the lower channel pattern CH1.

A first interlayer insulating layer 110 may be provided on the lower source/drain patterns SD1. The first interlayer insulating layer 110 may cover the lower source/drain patterns SD1. A second interlayer insulating layer 120 and a second active region AR2 may be provided on the first interlayer insulating layer 110.

The second active region AR2 may include an upper channel pattern CH2 and upper source/drain patterns SD2. The upper channel pattern CH2 may vertically overlap with the lower channel pattern CH1. The upper source/drain pattern SD2 may vertically overlap with the lower source/drain pattern SD1. The upper channel pattern CH2 may be interposed between the upper source/drain patterns SD2. The upper source/drain patterns SD2 may be disposed on both sides of the upper channel pattern CH2 and may be spaced apart from each other in the second direction D2 by the upper channel pattern CH2. The upper channel pattern CH2 may connect the upper source/drain patterns SD2 to each other.

The upper channel pattern CH2 may include fourth to sixth semiconductor patterns SP4, SP5, and SP6 that are sequentially stacked. The fourth to sixth semiconductor patterns SP4, SP5, and SP6 may be spaced apart from each other in the third direction D3. The fourth to sixth semiconductor patterns SP4, SP5, and SP6 of the upper channel pattern CH2 may include the same semiconductor material as the first to third semiconductor patterns SP1, SP2, and SP3 of the lower channel pattern CH1 described above.

At least one dummy channel pattern DSP may be interposed between the lower channel pattern CH1 and the upper channel pattern CH2. The dummy channel pattern DSP may be spaced apart from the lower source/drain pattern SD1. The dummy channel pattern DSP may be spaced apart from the upper source/drain pattern SD2. That is, the dummy channel pattern DSP is not connected to any source/drain pattern. The dummy channel pattern DSP may include a semiconductor material such as silicon (Si), germanium (Ge), or silicon germanium (SiGe), or may include a silicon-based insulating material such as a silicon oxide layer or a silicon nitride layer. In an embodiment of the present inventive concept, the dummy channel pattern DSP may include the silicon-based insulating material.

The upper source/drain patterns SD2 may be provided on an upper surface of the first interlayer insulating layer 110. Each of the upper source/drain patterns SD2 may be an epitaxial pattern formed by a selective epitaxial growth (SEG) process. For example, an upper surface of the upper source/drain patterns SD2 may be higher than an upper surface of the sixth semiconductor pattern SP6 of the upper channel pattern CH2.

The upper source/drain patterns SD2 may be doped with impurities to have a second conductivity type. The second conductivity type may be different from the first conductivity type of the lower source/drain patterns SD1. For example, the upper source/drain patterns SD2 may include at least one of silicon germanium (SiGe), silicon (Si), and silicon carbide (SiC). The upper source/drain patterns SD2 may be configured to provide tensile strain or compressive strain to the upper channel pattern CH2.

A second interlayer insulating layer 120 may cover the upper source/drain patterns SD2. An upper surface of the second interlayer insulating layer 120 may be substantially coplanar or coplanar with an upper surface of a first active contact 121 to be described later.

A gate electrode GE may be disposed on the lower channel pattern CH1 and the upper channel pattern CH2. The gate electrode GE may also be referred to as a word line WL. The gate electrode GE may have a bar shape extending in the first direction D1 when viewed in a plan view. The gate electrode GE may vertically overlap with the lower and upper channel patterns CH1 and CH2.

The gate electrode GE may be provided on an upper surface, a bottom surface, and both sidewalls of each of the first to sixth semiconductor patterns SP1 to SP6. For example, the transistor according to the present embodiment may include a three-dimensional field effect transistor (e.g., MBCFET or GAAFET) in which the gate electrode GE three-dimensionally surrounds the channel.

The gate electrode GE may include a lower gate electrode LGE and an upper gate electrode UGE. The lower gate electrode LGE is provided in the first active region AR1, and the upper gate electrode UGE is provided in the second active region AR2. The lower gate electrode LGE and the upper gate electrode UGE may vertically overlap each other. The lower gate electrode LGE and the upper gate electrode UGE may be connected to each other. For example, the gate electrode GE according to the present embodiment may be a common gate electrode in which the lower gate electrode LGE, which is on the lower channel pattern CH1, and the upper gate electrode UGE, which is on the upper channel pattern CH2, are connected to each other.

The lower gate electrode LGE may include a first portion PO1 interposed between the active pattern AP and the first semiconductor pattern SP1, a second portion PO2 interposed between the first semiconductor pattern SP1 and the second semiconductor pattern SP2, a third portion PO3 interposed between the second semiconductor pattern SP2 and the third semiconductor pattern SP3, and a fourth portion PO4 interposed between the third semiconductor pattern SP3 and the dummy channel pattern DSP.

The upper gate electrode UGE may include a fifth portion PO5 interposed between the dummy channel pattern DSP and the fourth semiconductor pattern SP4, a sixth portion PO6 interposed between the fourth semiconductor pattern SP4 and the fifth semiconductor pattern SP5, a seventh portion PO7 interposed between the fifth semiconductor pattern SP5 and the sixth semiconductor pattern SP6, and an eighth portion PO8 on the sixth semiconductor pattern SP6.

Gate spacers GS may be respectively disposed on both sidewalls of the gate electrode GE. Referring to FIG. 4A, the gate spacers GS may respectively be disposed on both sidewalls of the eighth portion PO8. The gate spacers GS may extend in the first direction D1 along the gate electrode GE. Upper surfaces of the gate spacers GS may be higher than an upper surface of the gate electrode GE. The upper surfaces of the gate spacers GS may be substantially coplanar or coplanar with an upper surface of the second interlayer insulating layer 120. For example, the gate spacers GS may include at least one of SiCN, SiCON, and/or SiN. As another example, the gate spacers GS may include a multi-layer including at least two of SiCN, SiCON, and/or SiN. A pair of liner layers LIN may be provided on each of the sidewalls of the fourth and fifth portions PO4 and PO5 of the gate electrode GE.

A gate capping pattern GP may be provided on an upper surface of the gate electrode GE. For example, the gate capping pattern GP may be disposed on the eighth portion P08 of the gate electrode GE. The gate capping pattern GP may extend in the first direction D1 along the gate electrode GE. For example, the gate capping pattern GP may include at least one of SiON, SiCN, SiCON, and/or SiN.

A gate insulating layer GI may be interposed between the gate electrode GE and the first to sixth semiconductor patterns SP1 to SP6. For example, the gate insulating layer GI may include a silicon oxide layer, a silicon oxynitride layer, and/or a high-k layer. In an embodiment of the present inventive concept, the gate insulating layer GI may include a silicon oxide layer, which directly contacts a surface of the semiconductor pattern SP1 to SP6, and a high-k layer disposed on the silicon oxide layer. For example, the gate insulating layer GI may include a multi-layer of a silicon oxide layer and a high-k layer.

The high-k layer may include a high-k material having a dielectric constant that is higher than that of the silicon oxide layer. For example, the high-k material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and/or lead zinc niobate.

An upper insulating layer 200 may be disposed on the second interlayer insulating layer 120. The upper insulating layer 200 may cover the gate spacers GS and the gate capping pattern GP.

A gate contact GC electrically connected to a gate electrode GE may be provided by penetrating the upper insulating layer 200 and the gate capping pattern GP. For example, the gate contact GC may include at least one of copper (Cu), aluminum (Al), ruthenium (Ru), cobalt (Co), tungsten (W), and/or molybdenum (Mo).

A first active contact 121 electrically connected to the upper source/drain pattern SD2 may be disposed. For example, the first active contact 121 may include a doped semiconductor and/or metal. For example, the metal may include at least one of copper (Cu), aluminum (Al), ruthenium (Ru), cobalt (Co), tungsten (W), and/or molybdenum (Mo).

The first active contact 121 may extend from the upper surface of the second interlayer insulating layer 120, pass through a portion of the second interlayer insulating layer 120, and penetrate into the interior of the upper source/drain pattern SD2. A lower surface of the first active contact 121 may be disposed in the upper source/drain pattern SD2.

An upper separation structure 121s at least partially surrounding a side surface of the first active contact 121 may be disposed. The upper separation structure 121s may be interposed between the first active contact 121 and the upper source/drain patterns SD2 and may extend in the third direction D3. For example, the upper separation structure 121s may be interposed between the first active contact 121 and the second interlayer insulating layer 120 and may extend between the first active contact 121 and the upper source/drain pattern SD2. The upper separation structure 121s may expose a lower surface of the first active contact 121. Unlike as shown, in some embodiments of the present inventive concept, the upper separation structure 121s may be omitted.

For example, the upper separation structure 121s may include a silicon-based insulating material such as a silicon oxide layer or a silicon nitride layer.

The upper insulating layer 200 may include a first upper insulating layer 210, a second upper insulating layer 220, a third upper insulating layer 230, a fourth upper insulating layer 240, and a fifth upper insulating layer 250 that are sequentially stacked. A first upper via UVI1 may be disposed in the first upper insulating layer 210. When viewed in a plan view, the first upper via UVI1 may vertically overlap the first active contact 121. An interlayer wiring 135 may be disposed in the second upper insulating layer 220. A second upper via UVI2 may be disposed in the third upper insulating layer 230. The interlayer wiring 135 may be disposed between the first upper via UVI1 and the second upper via UVI2. A first magnetic tunnel junction pattern MTJ1 may be disposed in the fourth upper insulating layer 240. A third upper via UVI3 may be disposed in the fifth upper insulating layer 250. The first magnetic tunnel junction pattern MTJ1 may be disposed between the second upper via UVI2 and the third upper via UVI3.

The first free magnetic tunnel junction pattern MTJ1 may include a first pinned magnetic pattern PL1, a first free magnetic pattern FL1, and a first tunnel barrier pattern TBL1 therebetween. The first pinned magnetic pattern PL1 may be disposed between the first tunnel barrier pattern TBL1 and the second upper via UVI2, and the first free magnetic pattern FL1 may be spaced apart from the first pinned magnetic pattern PL1 with the first tunnel barrier pattern TBL1 interposed therebetween. The first free magnetic pattern FL1 may be disposed between the first tunnel barrier pattern TBL1 and the third upper via UV13. The first magnetic tunnel junction pattern MTJ1 may be configured substantially the same as the magnetic tunnel junction pattern MTJ described with reference to FIGS. 2A and 2B.

The first magnetic tunnel junction pattern MTJ1 may be connected to the first active contact 121 through the second upper via UVI2, the interlayer wiring 135, and the first upper via UVI1. That is, the first magnetic tunnel junction pattern MTJ1 may be electrically connected to the upper source/drain pattern SD2 through the first active contact 121.

An upper wiring 235 may be disposed on an upper insulating layer 200 and the third upper via UVI3. For example, an upper surface of a third upper via UVI3 may be in contact with the upper wiring 235. An upper connection line CNL may be disposed on the upper wiring 235. For example, the upper wiring 235 may be in contact with the upper connection line CNL. A wiring insulating layer 300 covering the upper wiring 235 and the upper connection line CNL may be disposed on the upper insulating layer 200. A first wiring MI1 and a third wiring MI3 may be disposed on the wiring insulating layer 300. The first wiring MI1 may be connected to the upper connection line CNL through a fourth upper via UVI4 in the wiring insulating layer 300. For example, an upper surface of the fourth upper via UVI4 may be in contact with the first wiring MI1, and a lower surface of the fourth upper via UVI4 may be in contact with the upper connection line CNL.

The wiring insulating layer 300 may include a gate via GVI penetrating the wiring insulating layer 300. The gate contact GC may be electrically connected to the third wiring MI3 through the gate via GVI. The first wiring MI1 and the third wiring MI3 may extend in the second direction D2 and be spaced apart from each other in the first direction D1.

The first magnetic tunnel junction pattern MTJ1 may be electrically connected to the first wiring MI1 through the third upper via UVI3, the upper wiring 235, the upper connection line CNL, and the fourth upper via UVI4.

A backside wiring layer BSM may be disposed on the back surface 100b of the substrate 100. The backside wiring layer BSM may include a first lower insulating layer 10, a second lower insulating layer 20, and a third lower insulating layer 30 sequentially stacked from the back surface 100b of the substrate 100. A power transmission network layer PDN may be disposed on the backside wiring layer BSM.

A second active contact 11 electrically connected to the lower source/drain pattern SD1 may be disposed. According to embodiments of the present inventive concept, when viewed in a plan view, the first and second active contacts 121 and 11 may vertically overlap each other. For example, the second active contact 11 may include a doped semiconductor and/or a metal. For example, the metal may including at least one of copper (Cu), aluminum (Al), ruthenium (Ru), cobalt (Co), tungsten (W), and/or molybdenum (Mo).

The second active contact 11 may extend from the back surface 100b of the substrate 100, pass through the substrate 100, and extend into an interior of the lower source/drain pattern SD1. The upper surface of the second active contact 11 may be disposed in the lower source/drain pattern SD1.

A lower separation structure 11s at least partially surrounding the second active contact 11 may be disposed. The lower separation structure 11s may be interposed between the second active contact 11 and the lower source/drain patterns SD1 and may extend in the third direction D3. That is, the lower separation structure 11s may be interposed between the second active contact 11 and the substrate 100, and may extend between the second active contact 11 and the lower source/drain pattern SD1. The lower separation structure 11s may expose an upper surface of the second active contact 11. In embodiments of the present inventive concept, the lower separation structure 11s may be omitted.

The lower separation structure 11s may include a silicon-based insulating material such as a silicon oxide layer or a silicon nitride layer.

A second magnetic tunnel junction pattern MTJ2 may be disposed in the backside wiring layer BSM. For example, the second magnetic tunnel junction pattern MTJ2 may be disposed in the first lower insulating layer 10. The second magnetic tunnel junction pattern MTJ2 may be connected to the second active contact 11. When viewed in a plan view, the second magnetic tunnel junction pattern MTJ2 may be vertically overlapped with the second active contact 11. The second magnetic tunnel junction pattern MTJ2 may include a second free magnetic pattern FL2, a second pinned magnetic pattern PL2, and a second tunnel barrier pattern TBL2 therebetween. The second pinned magnetic pattern PL2 may be disposed between the second tunnel barrier pattern TBL2 and the second active contact 11, and the second free magnetic pattern FL2 may be spaced apart from the second pinned magnetic pattern PL2 with the second tunnel barrier pattern TBL2 therebetween. The second magnetic tunnel junction pattern MTJ2 may be electrically connected to the lower source/drain pattern SD1 through the second active contact 11.

According to embodiments of the present inventive concept, the first magnetic tunnel junction pattern MTJ1 may be an element constituting a one time programmable (OTP) memory cell. The OTP cell may have a very small resistance by programming the included magnetic tunnel junction pattern with a high voltage to cause a breakdown. That is, the first magnetic tunnel junction pattern MTJ1 may be in a blown state. Here, the blown state means a state in which two magnetic layers constituting the magnetic tunnel junction are short-circuited with each other. This may be achieved by applying a breakdown voltage to both ends of the two magnetic layers through a single programming operation to cause an insulating breakdown of the tunnel barrier layer between the magnetic layers. A resistance of the blown magnetic tunnel junction may be irreversible and may have a smaller value than a resistance of a non-blown magnetic tunnel junction. In conclusion, the first tunnel barrier pattern TBP1 of the first magnetic tunnel junction pattern MTJ1 is insulated-broken and the first magnetic tunnel junction pattern MTJ1 may have an irreversible resistance state. The second magnetic tunnel junction pattern MTJ2 may be an element constituting a main memory cell. The second magnetic tunnel junction pattern MTJ2 may be in a non-blown state and may have a reversible resistance state. The first magnetic tunnel junction pattern MTJ1 may have a resistance value smaller than that of the second magnetic tunnel junction pattern MTJ2.

According to an embodiment of the present inventive concept, the second magnetic tunnel junction pattern MTJ2 may be in a blown state and may have an irreversible resistance state. The first magnetic tunnel junction pattern MTJ1 may be in a non-blown state and may have a reversible resistance state. That is, the second magnetic tunnel junction pattern MTJ2 may function as an OTP cell, and the first magnetic tunnel junction pattern MTJ1 may function as a main memory cell.

According to embodiments of the present inventive concept, one of the first magnetic tunnel junction pattern MTJ1 or the second magnetic tunnel junction pattern MTJ2 may be in a blown state, and the other may be in a non-blown state.

A first lower via BVI1 may be provided in the second lower insulating layer 20. A lower wiring 35 may be provided in the third lower insulating layer 30. The first lower via BVI1 may be disposed between the second magnetic tunnel junction pattern MTJ2 and the lower wiring 35. For example, the upper surface of the first lower via BVI1 may be in contact with the second magnetic tunnel junction pattern MTJ2, and a lower surface of the first lower via BVI1 may be in contact with the lower wiring 35.

A through-contact plug TCP, which connects the upper wiring 235 and the lower wiring 35 to each other, may be provided. In detail, the through-contact plug TCP may penetrate the upper insulating layer 200, the first and second interlayer insulating layers 110 and 120, and the substrate 100, and may further penetrate a portion of the backside wiring layer BSM to connect the upper wiring 235 and the lower wiring 35 to each other. For example, an upper surface of the through-contact plug TCP may be in contact with the upper wiring 235, and a lower surface of the through-contact plug TCP may be in contact with the lower wiring 35. When viewed in a plan view, the through-contact plug TCP might not vertically overlap the lower and upper source/drain patterns SD1 and SD2 with each other. For example, the through-contact plug TCP may be spaced apart from the lower and upper source/drain patterns SD1 and SD2. In addition, the lower source/drain pattern SD1 may be electrically connected to the first wiring MI1 through the through-contact plug TCP. The lower source/drain pattern SD1 and the upper source/drain pattern SD2 may be electrically connected to the first wiring MI1 in common. That is, the first wiring MI1 may be electrically connected to the first and second magnetic tunnel junction patterns MTJ1 and MTJ2, the first and second active contacts 121 and 11, and the lower and upper source/drain patterns SD1 and SD2.

A backside contact 50 may be provided and may penetrate the backside wiring layer BSM, the substrate 100, and the lower source/drain pattern SD1 to extend into the interior of the upper source/drain pattern SD2. An upper surface of the backside contact 50 may be disposed in the interior of the upper source/drain pattern SD2. For example, the backside contact 50 may include a doped semiconductor and/or a metal. For example, the metal may include at least one of copper (Cu), aluminum (Al), ruthenium (Ru), cobalt (Co), tungsten (W), and/or molybdenum (Mo).

A lower connection line BCNL and a second wiring MI2 may be provided in the power transmission network layer PDN. The backside contact 50 may be disposed on an upper surface of the lower connection line BCNL. For example, an upper surface of the lower connection line BCNL may be in contact with a lower surface of a backside contact 50. A lower surface of the lower connection line BCNL may be disposed on the second wiring MI2. In embodiments of the present inventive concept, a lower surface of the lower connection line BCNL may be in contact with the second wiring MI2. That is, the lower and upper source/drain patterns SD1 and SD2 may be electrically connected to the second wiring MI2 through the backside contact 50 and the lower connection line BCNL. In embodiments of the present inventive concept, lower vias may be additionally disposed between the lower connection line BCNL and the second wiring MI2, and the lower connection line BCNL and the second wiring MI2 may be electrically connected through the lower vias.

According to embodiments of the present inventive concept, two vertically stacked transistors may be used, thereby increasing integration of a magnetic memory device. In addition, the wiring (e.g., BSM, MI2, and BCNL) on the back surface 100b of the substrate 100 may reduce wiring complexity. In addition, the first and second magnetic tunnel junction patterns MTJ1 and MTJ2 may be disposed on the front and back surfaces 100a and 100b of the substrate 100, respectively. That is, the OTP cell and the main cell are respectively disposed on the front and back surfaces 100a and 100b of the substrate 100. Thus, the OTP cell area might not be separately allocated, and the cell area may be reduced.

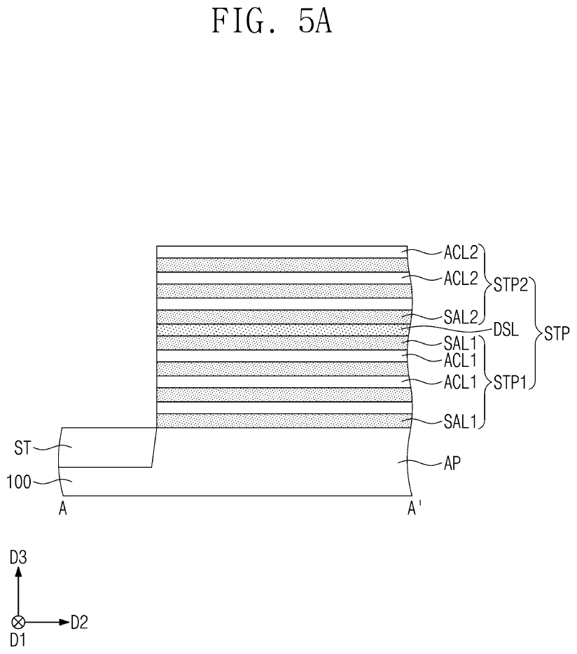

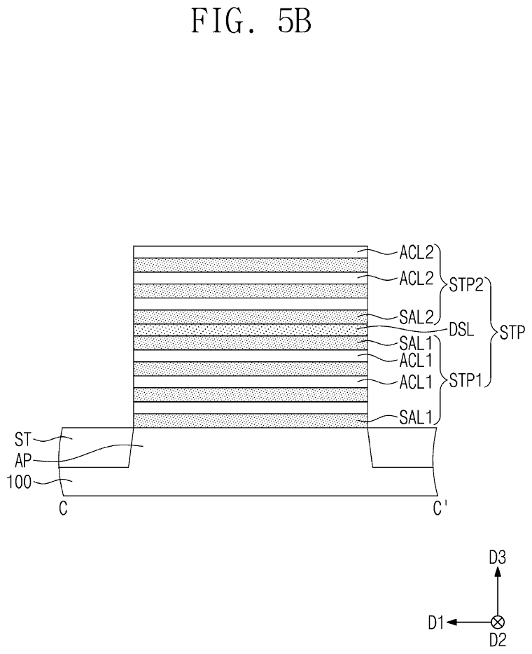

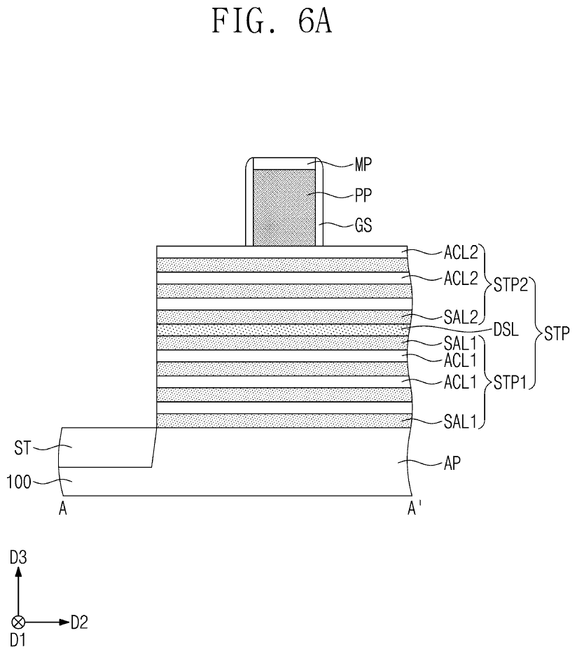

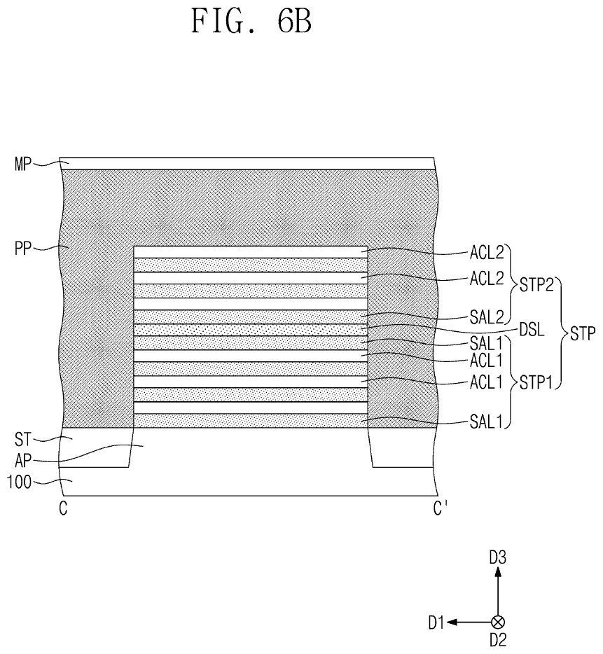

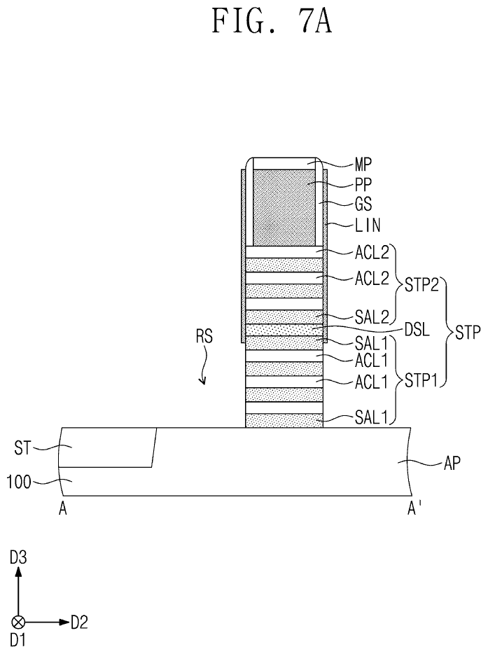

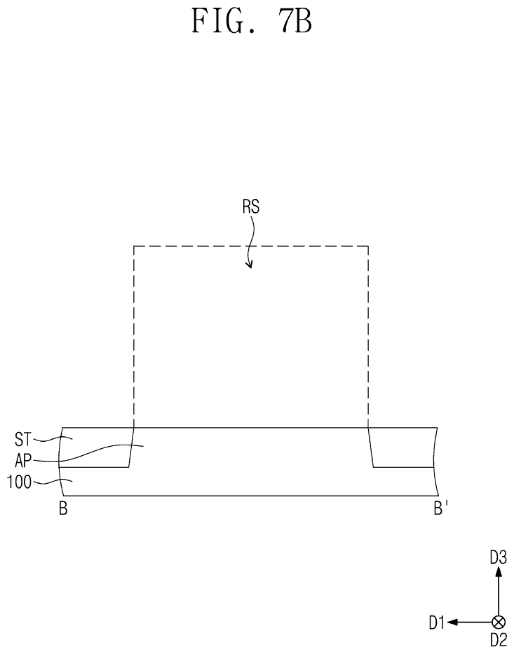

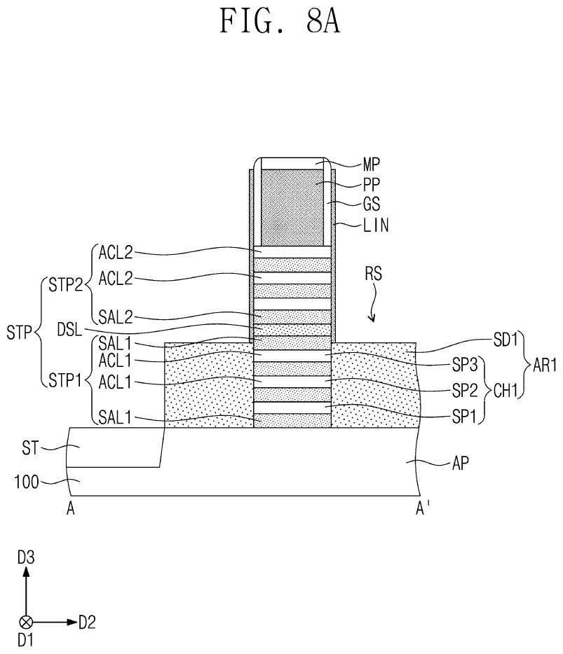

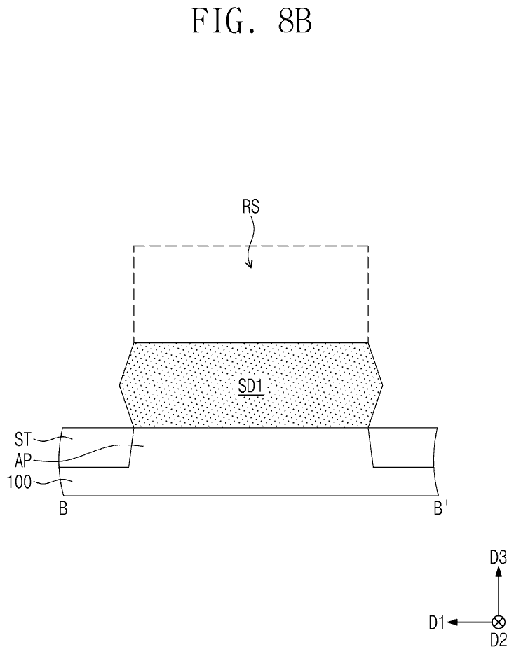

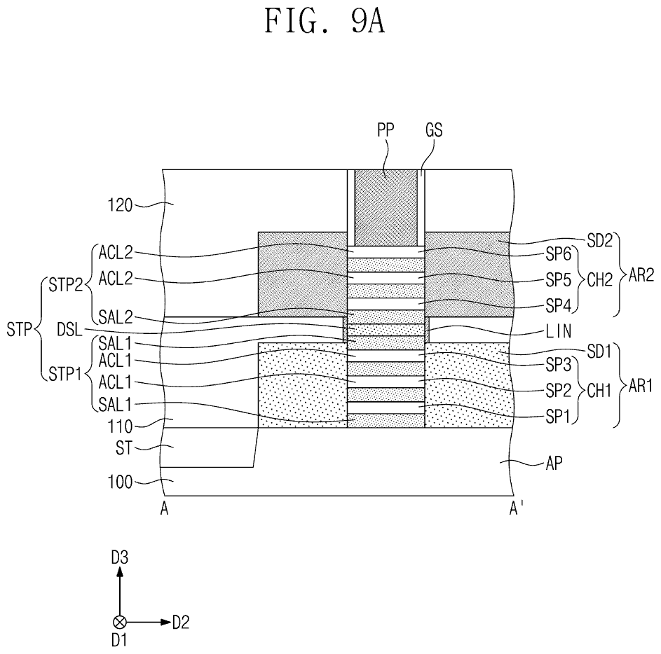

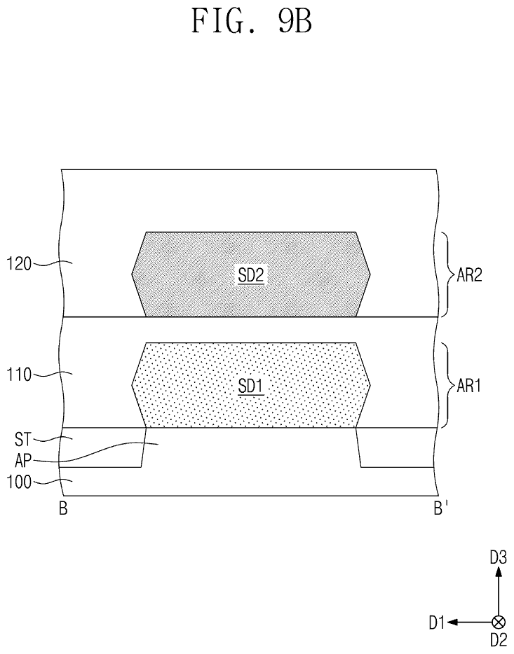

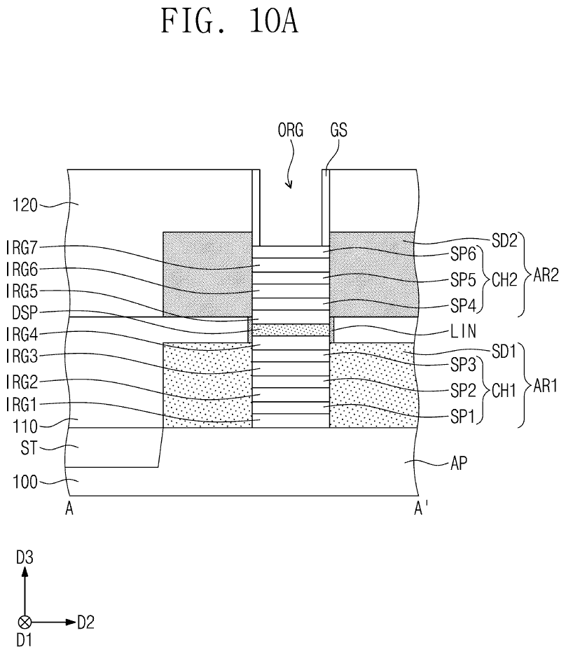

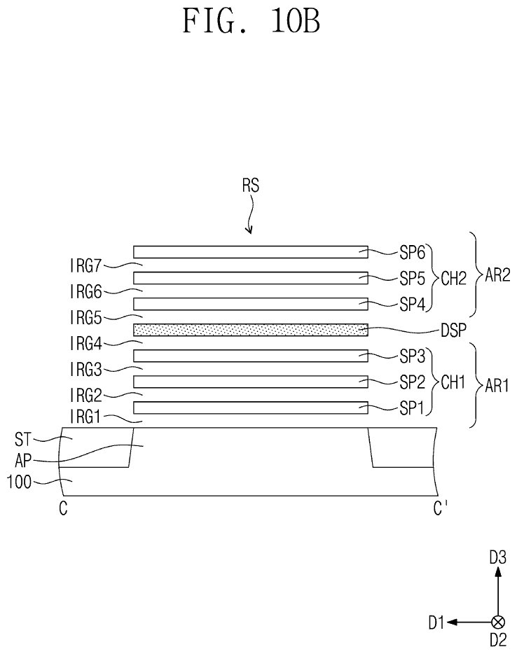

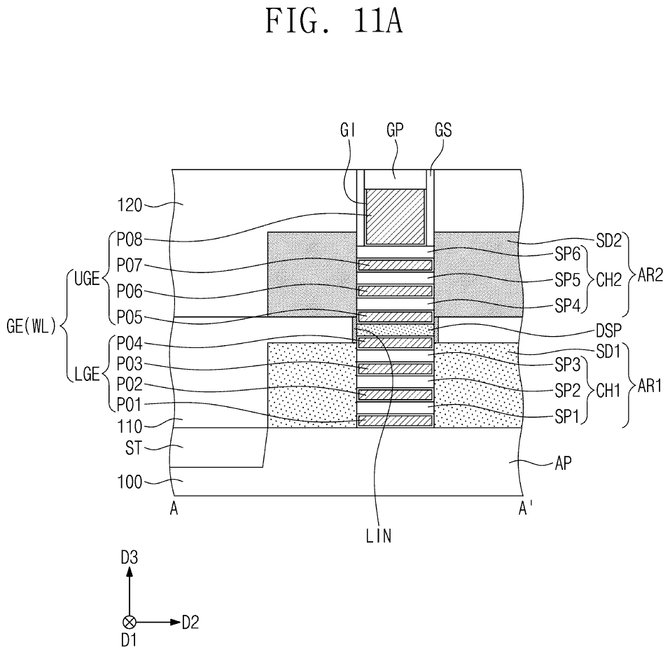

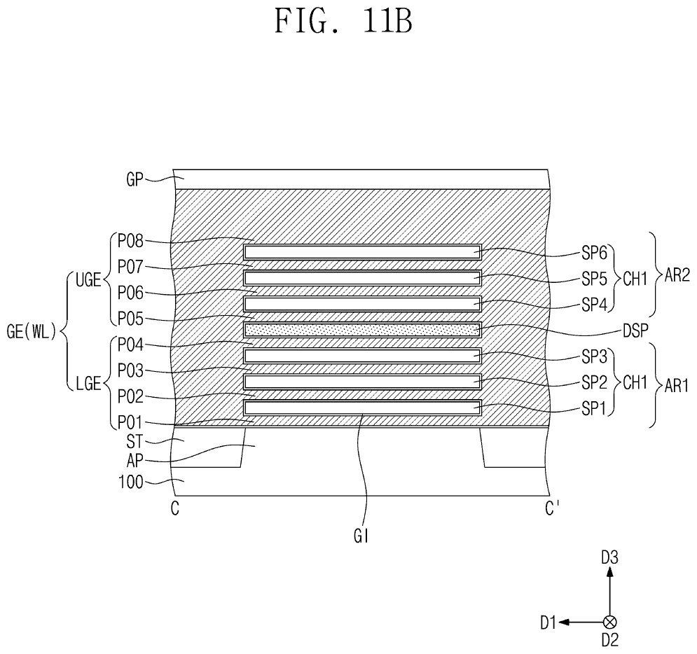

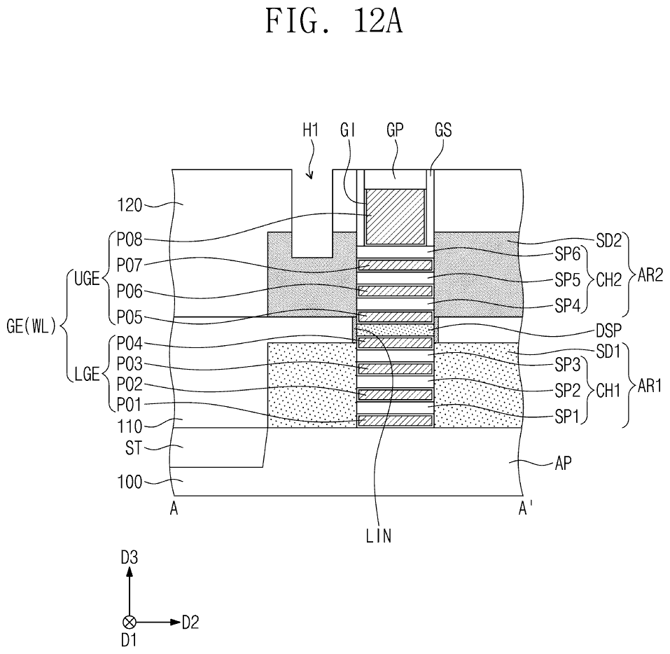

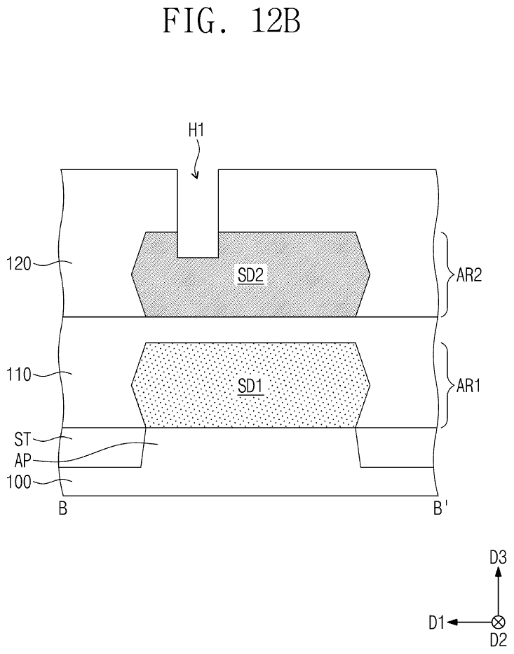

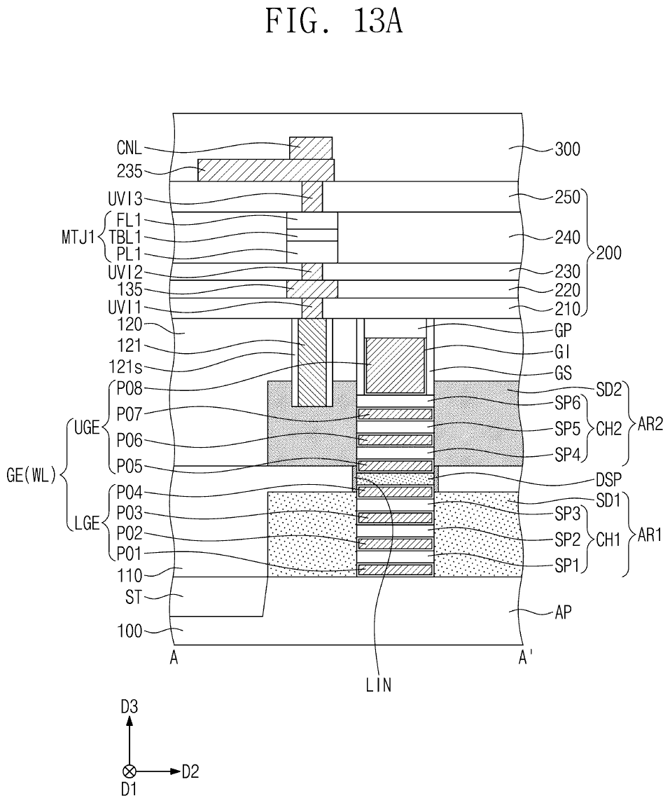

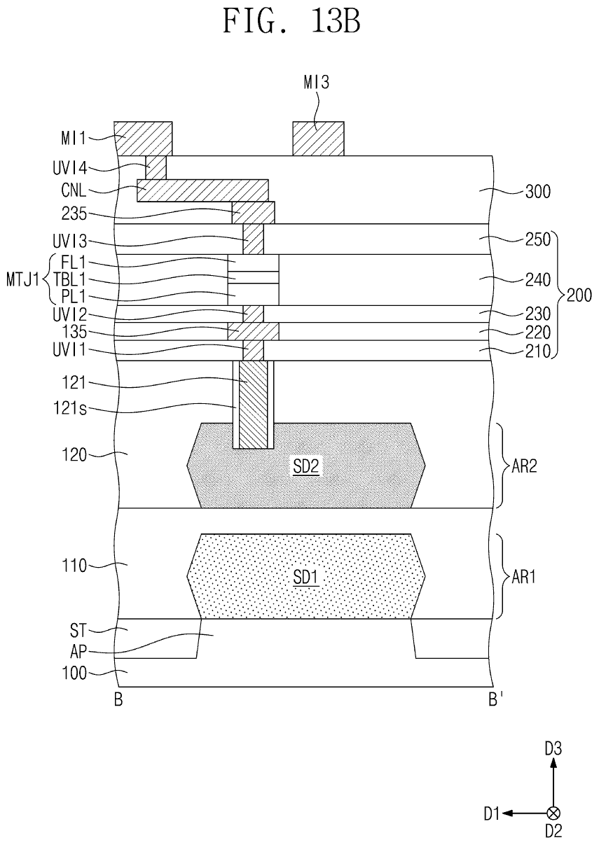

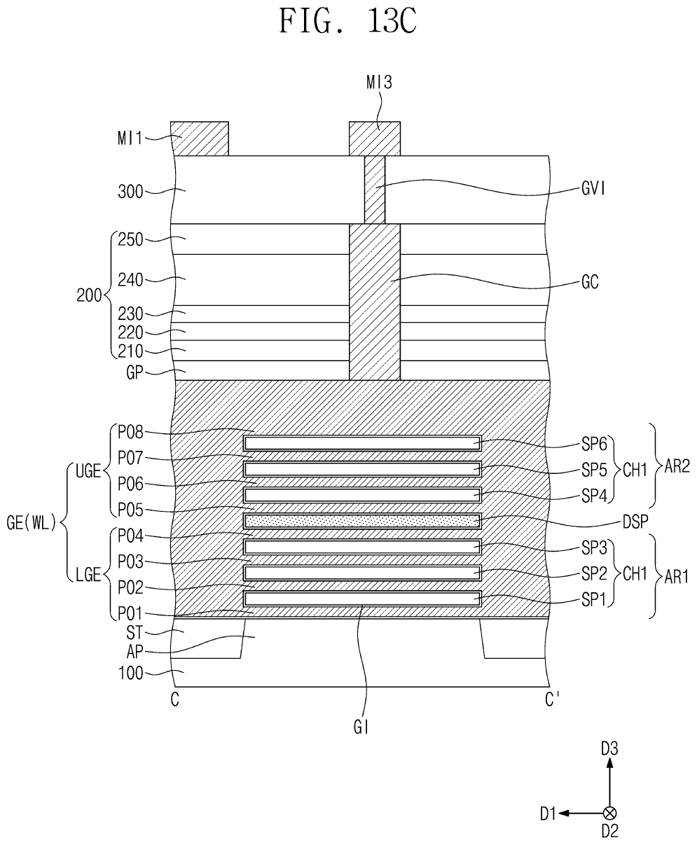

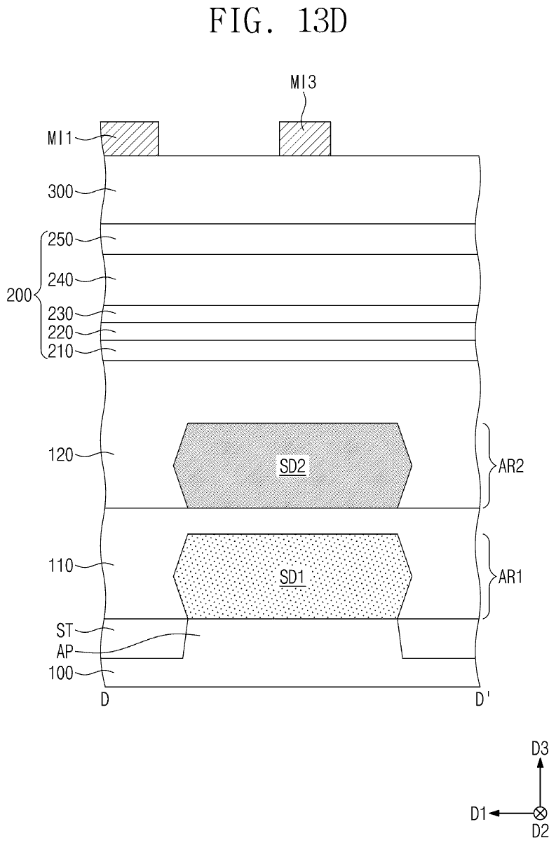

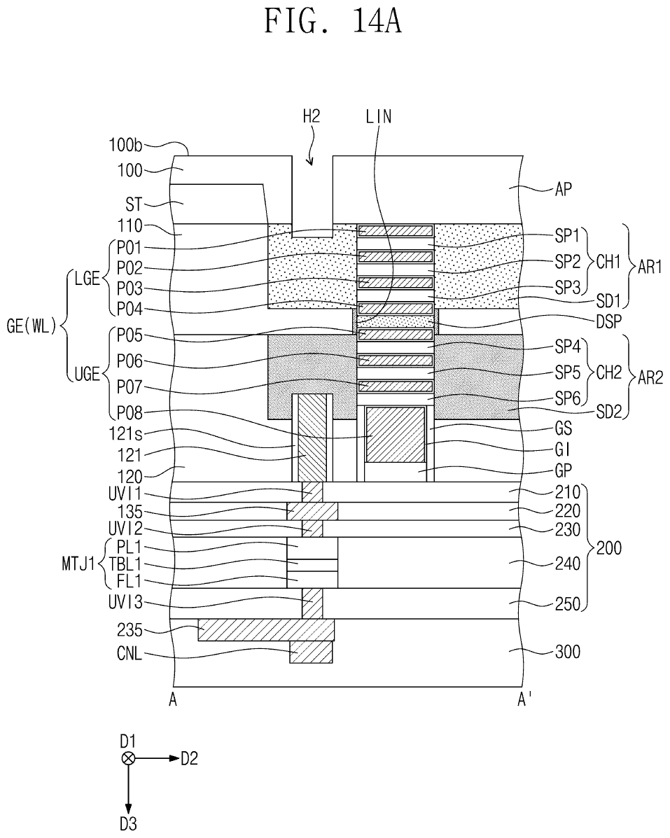

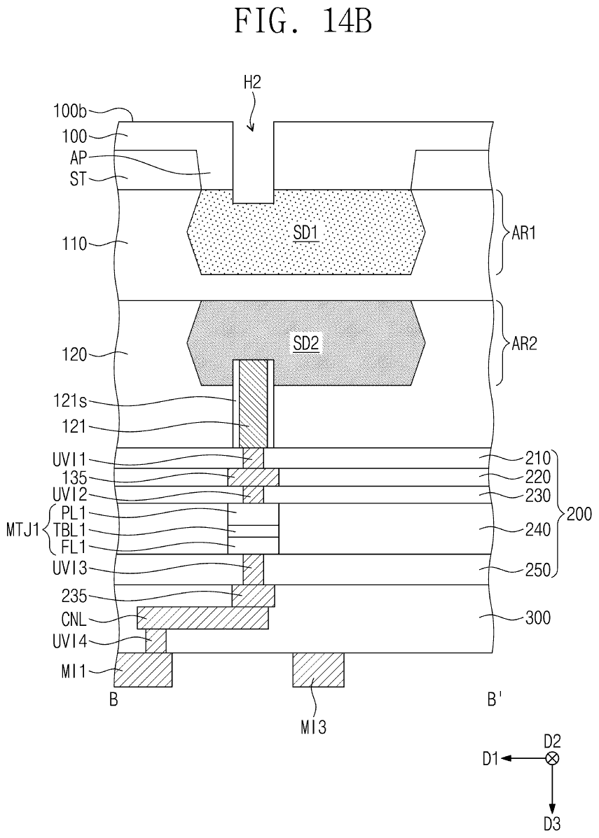

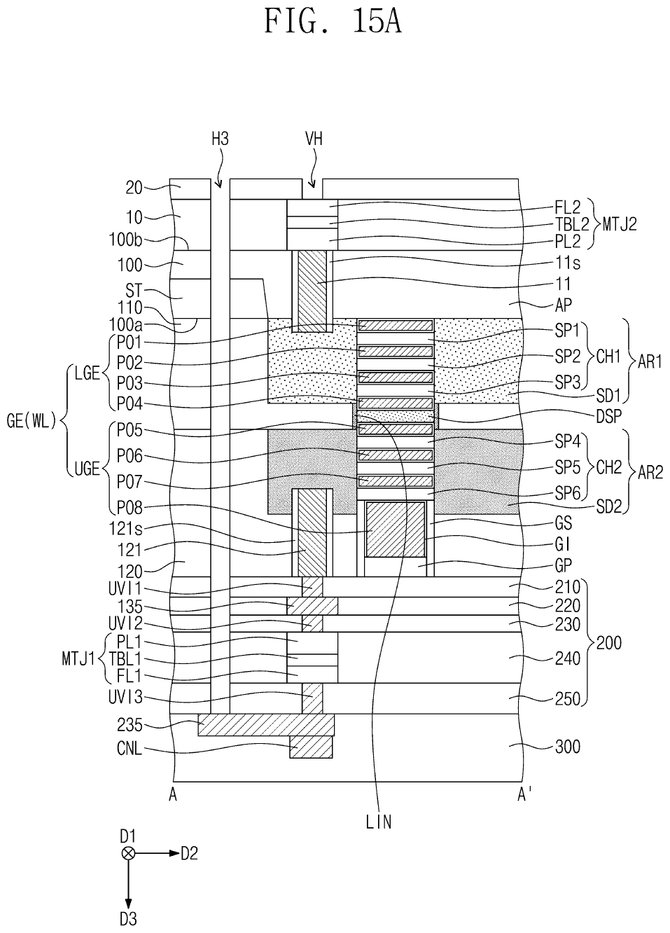

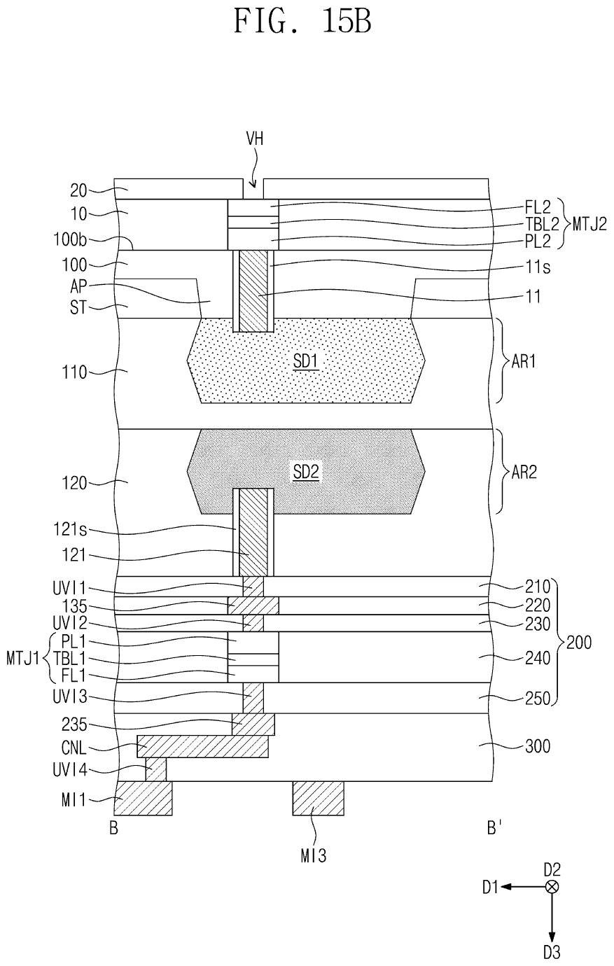

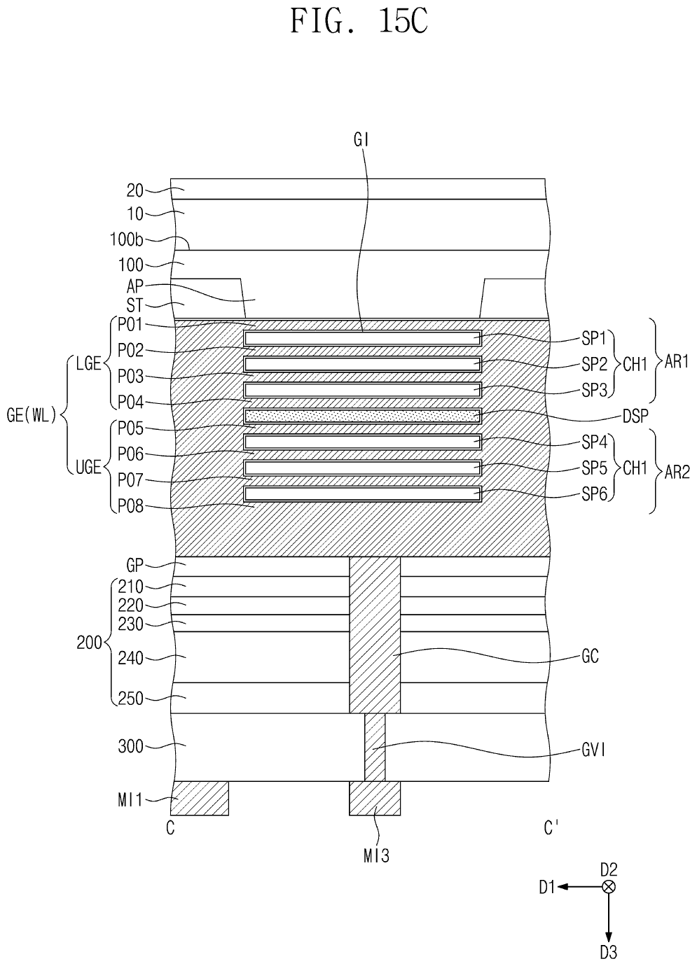

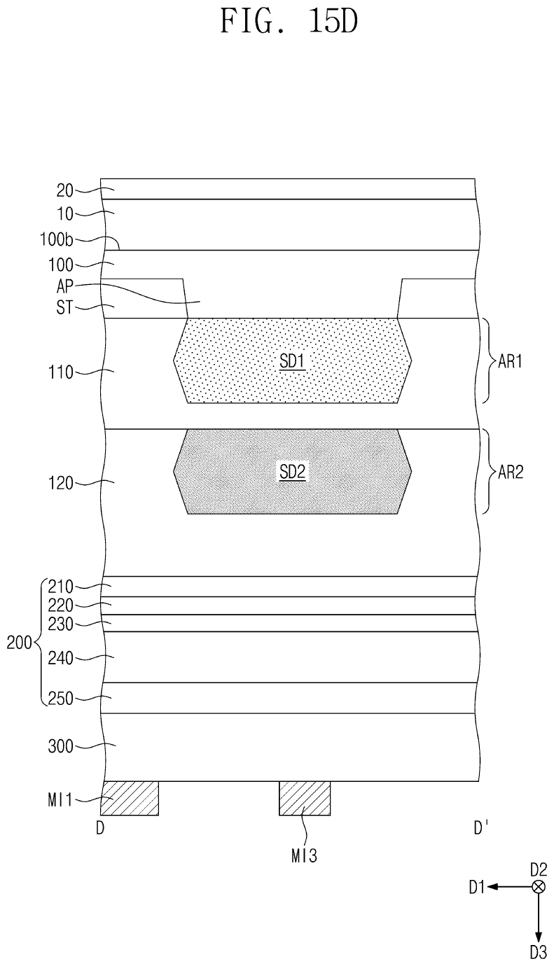

FIGS. 5A to 16D are cross-sectional views for illustrating a method of manufacturing a magnetic memory device according to an embodiment of the present inventive concept. In detail, FIGS. 5A, 6A, 7A, 8A, 9A, 10A, 11A, 12A, 13A, 14A, 15A, and 16A are cross-sectional views corresponding to line A-A′ of FIG. 3. FIGS. 7B, 8B, 9B, 12B, 13B, 14B, 15B, and 16B are cross-sectional views corresponding to line B-B′ of FIG. 3. FIGS. 5B, 6B, 10B, 11B, 13C, 15C, and 16C are cross-sectional views corresponding to line C-C′ of FIG. 3. FIGS. 13D, 15D, and 16D are cross-sectional views corresponding to line D-D′ of FIG. 3. To simplify the explanation, any content overlapping with that described above is omitted or briefly discussed.

Referring to FIG. 3, 5A, and 5B, first sacrificial layers SAL1 and first active layers ACL1 may be alternately stacked on a substrate 100. For example, the first sacrificial layers SAL1 may include one of silicon (Si), germanium (Ge), and silicon germanium (SiGe), and the first active layers ACL1 may include another one of silicon (Si), germanium (Ge), and silicon germanium (SiGe). For example, the first sacrificial layers SAL1 may include silicon germanium (SiGe), and the first active layers ACL1 may include silicon (Si).

A separation layer DSL may be formed on the uppermost first active layer ACL1. According to embodiments of the present inventive concept, a thickness of the separation layer DSL may be substantially the same as a thickness of the first sacrificial layer SAL1.

Second sacrificial layers SAL2 and second active layers ACL2 may be alternately stacked on the separation layer DSL. Each of the second sacrificial layers SAL2 may include the same material as the first sacrificial layer SAL1, and each of the second active layers ACL2 may include the same material as the first active layer ACL1. The separation layer DSL may be interposed between the first sacrificial layer SAL1 and the second sacrificial layer SAL2.

The stacked first and second sacrificial layers SAL1 and SAL2, the first and second active layers ACL1 and ACL2, and the separation layer DSL may be patterned to form a stacked pattern STP. Forming the stacked pattern STP may include forming a hard mask pattern on the uppermost second active layer ACL2, and sequentially etching the stacked layers SAL1, SAL2, ACL1, ACL2, and DSL on the substrate 100 using the hard mask pattern as an etching mask.

While the stacked pattern STP is formed, the upper portion of the substrate 100 may be patterned to form a trench defining an active pattern AP. The stacked pattern STP may have a shape extending in the second direction D2.

The stacked pattern STP may include a lower stacked pattern STP1 on the active pattern AP, an upper stacked pattern STP2 on the lower stacked pattern STP1, and the separation layer DSL between the lower and upper stacked patterns STP1 and STP2. The lower stacked pattern STP1 may include alternately stacked first sacrificial layers SAL1 and first active layers ACL1. The upper stacked pattern STP2 may include alternately stacked second sacrificial layers SAL2 and second active layers ACL2.

A device isolation layer ST filling the trench may be formed on the substrate 100. Forming the device isolation layer ST may include, for example, forming an insulating layer covering the active pattern AP and the stacked pattern STP on the entire surface of the substrate 100 and recessing the insulating layer until the stacked pattern STP is exposed.

Referring to FIG. 3, 6A, and 6B, a sacrificial pattern PP may be formed across the stacked pattern STP. The sacrificial pattern PP may be formed in a line shape extending in the first direction D1. Forming the sacrificial pattern PP may include, for example, forming a sacrificial layer on the entire surface of the substrate 100, forming a hard mask pattern MP on the sacrificial layer, and etching the sacrificial layer using the hard mask pattern MP as an etching mask. The sacrificial layer may include, for example, amorphous silicon and/or polysilicon.

Gate spacers GS may be formed on each of the two sidewalls of the sacrificial pattern PP. Forming the gate spacers GS may include, for example, forming a spacer layer conformally on the entire surface of the substrate 100, and etching the spacer layer using an anisotropic etching process. The spacer layer may include, for example, at least one of SiCN, SiCON, and SiN.

Referring to FIG. 3, 7A, and 7B, recesses RS may be formed on both sides of the sacrificial pattern PP. Forming the recesses RS may be performed, for example, by performing an etching process on the stacked pattern STP using the gate spacers GS and the hard mask pattern MP as an etching mask.

Liner layers LIN may be formed on each sidewall of the upper stacked pattern STP2. The liner layers LIN may prevent the upper stacked pattern STP2 from being exposed by the recesses RS. The liner layers LIN may expose the lower stacked pattern STP1. For example, the liner layers LIN may include silicon nitride.

Referring to FIG. 3, 8A, and 8B, lower source/drain patterns SD1 may be formed in the recesses RS, respectively. Specifically, a first selective epitaxial growth (SEG) process may be performed using a sidewall of an exposed lower stacked pattern STP1 as a seed layer, thereby forming the lower source/drain patterns SD1. The lower source/drain patterns SD1 may be grown using the first active layers ACL1 and the active pattern AP, which are exposed by the recess RS, as seeds. For example, the first SEG process may include a chemical vapor deposition (CVD) process or a molecular beam epitaxy (MBE) process.

During the first SEG process, for example, impurities may be injected in-situ into the lower source/drain patterns SD1. As another example, impurities may be injected into the lower source/drain patterns SD1 after the lower source/drain patterns SD1 are formed. The lower source/drain patterns SD1 may be doped to have a first conductivity type.

First active layers ACL1 interposed between the lower source/drain patterns SD1 may form the lower channel pattern CH1. That is, first to third semiconductor patterns SP1, SP2, and SP3 of the lower channel pattern CH1 may be formed from the first active layers ACL1. The lower channel pattern CH1 and the lower source/drain patterns SD1 may form a first active region AR1.

The sidewall of the upper stacked pattern STP2 may be covered by the liner layer LIN. For example, the second active layers ACL2 of the upper stacked pattern STP2 might not be exposed by the liner layer LIN during the first SEG process. Therefore, a separate semiconductor layer might not be grown on the upper stacked pattern STP2 during the first SEG process.

Referring to FIG. 3, 9A, and. 9B, a first interlayer insulating layer 110 covering the lower source/drain patterns SD1 may be formed. An upper surface of the first interlayer insulating layer 110 may be recessed to be lower than a bottom surface of the lowermost second active layer ACL2 of the plurality of second active layers ACL2.

A portion of the liner layer LIN exposed by the recess RS may be removed. The liner layer LIN remaining covered by the first interlayer insulating layer 110 may cover the sidewall of the separation layer DSL. As the liner layer LIN is removed, the second active layers ACL2 may be exposed by the recess RS.

Upper source/drain patterns SD2 may be formed on both sidewalls of the upper stacked pattern STP2, respectively. For example, a second SEG process may be performed by using the sidewall of the upper stacked pattern STP2 as a seed layer, thereby forming the upper source/drain patterns SD2. The upper source/drain patterns SD2 may be grown by using the second active layers ACL2, which is exposed by the recess RS, as seeds. The upper source/drain patterns SD2 may be doped to have a second conductivity type different from the first conductivity type.

The second active layers ACL2 interposed between the upper source/drain patterns SD2 may form an upper channel pattern CH2. That is, the fourth to sixth semiconductor patterns SP4, SP5, and SP6 of the upper channel pattern CH2 may be formed from the second active layers ACL2. The upper channel pattern CH2 and the upper source/drain patterns SD2 may form a second active region AR2.

A second interlayer insulating layer 120 covering the hard mask pattern MP, the gate spacers GS, and the upper source/drain patterns SD2 may be formed on the first interlayer insulating layer 110.

The second interlayer insulating layer 120 may be planarized until an upper surface of the sacrificial pattern PP is exposed. For example, the planarization of the second interlayer insulating layer 120 may be performed using an etch back or chemical mechanical polishing (CMP) process. During the planarization process, the hard mask pattern MP may be completely removed. As a result, an upper surface of the second interlayer insulating layer 120 may be coplanar with the upper surface of the sacrificial pattern PP and the upper surfaces of the gate spacers GS.

Referring to FIG. 3, 10A, and 10B, the sacrificial pattern PP may be selectively removed. The sacrificial pattern PP may be removed, and an outer region ORG exposing the lower and upper channel patterns CH1 and CH2 may be formed. Forming the outer region ORG may be performed, for example, by a wet etching process using an etchant that selectively etches the sacrificial pattern PP.

According to embodiments of the present inventive concept, the separation layer DSL exposed through the outer region ORG may be replaced with a dummy channel pattern DSP. According to an embodiment of the present inventive concept, the separation layer DSL may remain intact to form the dummy channel pattern DSP.

The first and second sacrificial layers SAL1 and SAL2 exposed through the outer region ORG may be selectively removed, thereby forming first to seventh inner regions IRG1 to IRG7, respectively. For example, an etching process that selectively etches the first and second sacrificial layers SAL1 and SAL2 may be performed, and only the first and second sacrificial layers SAL1 and SAL2 may be removed while leaving the first to sixth semiconductor patterns SP1 to SP6 and the dummy channel pattern DSP intact.

By selectively removing the first and second sacrificial layers SAL1 and SAL2, the first to third semiconductor patterns SP1, SP2, and SP3 may remain on the first active region AR1, and the fourth to sixth semiconductor patterns SP4, SP5, and SP6 may remain on the second active region AR2. The dummy channel pattern DSP may remain between the third semiconductor pattern SP3 and the fourth semiconductor pattern SP4.

An empty space between the active pattern AP and the first semiconductor pattern SP1 may be defined as a first inner region IRG1. An empty space between the first semiconductor pattern SP1 and the second semiconductor pattern SP2 may be defined as a second inner region IRG2. An empty space between the second semiconductor pattern SP2 and the third semiconductor pattern SP3 may be defined as a third inner region IRG3. An empty space between the third semiconductor pattern SP3 and the dummy channel pattern DSP may be defined as a fourth inner region IRG4. An empty space between the dummy channel pattern DSP and the fourth semiconductor pattern SP4 may be defined as a fifth inner region IRG5. An empty space between the fourth semiconductor pattern SP4 and the fifth semiconductor pattern SP5 may be defined as a sixth inner region IRG6, and an empty space between the fifth semiconductor pattern SP5 and the sixth semiconductor pattern SP6 may be defined as a seventh inner region IRG7.

Referring to FIG. 3, 11A and 11B, a gate insulating layer GI may be conformally formed on the exposed first to sixth semiconductor patterns SP1 to SP6. A gate electrode GE may be formed on the gate insulating layer GI. Forming the gate electrode GE may include forming first to seventh portions PO1 to PO7 in the first to seventh inner regions IRG1 to IRG7, respectively, and forming an eighth portion PO8 in the outer region ORG.

The gate electrode GE may be recessed, thereby reducing a height thereof. A gate capping pattern GP may be formed on the recessed gate electrode GE. A planarization process may be performed on the gate capping pattern GP such that an upper surface of the gate capping pattern GP is substantially coplanar or coplanar with an upper surface of the second interlayer insulating layer 120.

Referring to FIG. 3, 12A and 12B, a first hole H1 on one side of the gate electrode GE may be formed. The first hole H1 may extend from the upper surface of the second interlayer insulating layer 120 to the upper source/drain pattern SD2. The first hole H1 may be formed by penetrating a portion of the second interlayer insulating layer 120 and the upper source/drain pattern SD2. A bottom surface of the first hole H1 may be disposed in the upper source/drain pattern SD2.

Referring to FIGS. 3 and 13A to 13D, a first active contact 121 and an upper separation structure 121s may be formed. For example, forming the upper separation structure 121s may include forming an upper separation layer that conformally covers an inner surface and a bottom surface of the first hole H1, and removing a portion of the upper separation layer that covers the bottom surface of the first hole H1 through an anisotropic etching process. The upper separation structure 121s may conformally cover the inner wall of the first hole H1. The upper separation structure 121s might not cover the bottom surface of the first hole H1 and may expose the upper source/drain pattern SD2.

A first active contact 121 may be formed on the remainder of the first hole H1. Forming the first active contact 121 may include, for example, forming an upper layer that fills the remainder of the first hole H1 and may be disposed on the second interlayer insulating layer 120, and recessing the upper layer until the upper surface of the second interlayer insulating layer 120 is exposed. A lower surface of the first active contact 121 may be disposed on the upper source/drain pattern SD2. For example, A lower surface of the first active contact 121 may be in contact with the upper source/drain pattern SD2. However, according to an embodiment of the present inventive concept, the upper separation structure 121s may be omitted.

An upper insulating layer 200 may be formed on the second interlayer insulating layer 120. The upper insulating layer 200 may include a first upper insulating layer 210, a second upper insulating layer 220, a third upper insulating layer 230, a fourth upper insulating layer 240, and a fifth upper insulating layer 250 that are sequentially stacked.

A first upper via UVI1 connected to the first active contact 121 may be formed in the first upper insulating layer 210. An interlayer wiring 135 may be formed in the second upper insulating layer 220. The interlayer wiring 135 may be connected to the first upper via UVI1. A second upper via UVI2 may be formed in the third upper insulating layer 230. The second upper via UVI2 may be connected to the interlayer wiring 135.

A first magnetic tunnel junction pattern MTJ1 may be formed in the fourth upper insulating layer 240. The first magnetic tunnel junction pattern MTJ1 may be connected to and disposed on the second upper via UVI2. For example, the first magnetic tunnel junction pattern MTJ1 may be in direct contact with an upper surface of the second upper via UVI2. Forming the first magnetic tunnel junction pattern MTJ1 may include, for example, forming the third upper insulating layer 230 and then, before forming the fourth upper insulating layer 240, sequentially stacking a pinned magnetic layer, a tunnel barrier layer, and a free magnetic layer on the third upper insulating layer 230, forming a mask pattern on the free magnetic layer, sequentially anisotropically etching the free magnetic layer, the tunnel barrier layer, and the pinned magnetic layer using the mask pattern as an etching mask until the upper surface of the third upper insulating layer 230 is exposed, and removing the mask pattern.

After forming the first magnetic tunnel junction pattern MTJ1, the fourth upper insulating layer 240 and the fifth upper insulating layer 250 may be formed on the third upper insulating layer 230. A third upper via UVI3 may be formed in the fifth upper insulating layer 250. The third upper via UVI3 may be disposed on the first magnetic tunnel junction pattern MTJ1. For example, the lower surface of the third upper via UVI3 may be in contact with an upper surface of the first magnetic tunnel junction pattern MTJ1.

After the upper insulating layer 200 is formed, a gate contact GC that penetrates the upper insulating layer 200 and the gate capping pattern GP and connects to the gate electrode GE may be formed.

An upper wiring 235, an upper connection line CNL, and a wiring insulating layer 300 covering the upper wiring 235 and the upper connection line CNL may be formed on the upper insulating layer 200. A fourth upper via UVI4 that is connected to the upper connection line CNL may be formed in the wiring insulating layer 300. A gate via GVI connected to the gate contact GC may be formed by penetrating the wiring insulating layer 300. A first wiring MI1 and a third wiring MI3 may be formed on the wiring insulating layer 300. The first and third wirings MI1 and MI3 may include, for example, forming a wiring line layer MIDO and patterning the wiring line layer. The first and third wirings MI1 and MI3 may extend in the second direction D2 crossing the gate electrode GE. The first wiring MI1 may be connected to and disposed on the fourth upper via UVI4. For example, the first wiring MI1 may be in contact with an upper surface of the fourth upper via UVI4. The third wiring MI3 may be connected to and disposed the gate via GVI. For example, the third wiring MI3 may be in contact with an upper surface of the gate via GVI.

Referring to FIG. 3, 14A and 14B, the magnetic memory device being manufactured may be flipped over. That is, the substrate 100 may be flipped over so that the back surface 100b of the substrate 100 faces upward.

Subsequently, a second hole H2 penetrating the substrate 100 may be formed. The second hole H2 may extend from a back surface 100b of the substrate 100 to the inside of the lower source/drain pattern SD1. The second hole H2 may be formed by penetrating the substrate 100 and a portion of the lower source/drain pattern SD1. A bottom surface of the second hole H2 may be disposed inside the lower source/drain pattern SD1.

Referring to FIGS. 3 and 15A to 5D, a second active contact 11 and a lower separation structure 11s may be formed. Forming the lower separation structure 11s may include, for example, forming a lower separation layer that conformally covers the inner surface and bottom surface of the second hole H2, and removing a portion of the lower separation layer that covers the bottom surface of the second hole H2 through an anisotropic etching process. The lower separation structure 11s may conformally cover an inner wall of the second hole H2. The lower separation structure 11s might not cover the bottom surface of the second hole H2 and may expose the lower source/drain pattern SD1.

The second active contact 11 may be formed on the remainder of the second hole H2. Forming the second active contact 11 may include, for example, forming a lower layer that fills the remainder of the second hole H2 and that may be disposed on the back surface 100b of the substrate 100, and recessing the lower layer until the back surface 100b of the substrate 100 is exposed. However, according to an embodiment of the present inventive concept, the lower separation structure 11s may be omitted.

A second magnetic tunnel junction pattern MTJ2 may be formed on the back surface 100b of the substrate 100. Forming the second magnetic tunnel junction pattern MTJ2 may be performed through substantially the same process as forming the first magnetic tunnel junction pattern MTJ1 described above.

A first lower insulating layer 10 and a second lower insulating layer 20 may be formed on the back surface 100b of the substrate 100. After the second lower insulating layer 20 is formed, a via hole VH and a third hole H3 may be formed. The via hole VH may penetrate the second lower insulating layer 20 to expose the second magnetic tunnel junction pattern MTJ2. The third hole H3 may be formed to penetrate the second lower insulating layer 20, the first lower insulating layer 10, the substrate 100, the first and second interlayer insulating layers 110 and 120, and the upper insulating layer 200. A bottom surface of the third hole H3 may expose the upper wiring 235. The third hole H3 might not overlap the lower and upper source/drain patterns SD1 and SD2 when viewed in a plan view.

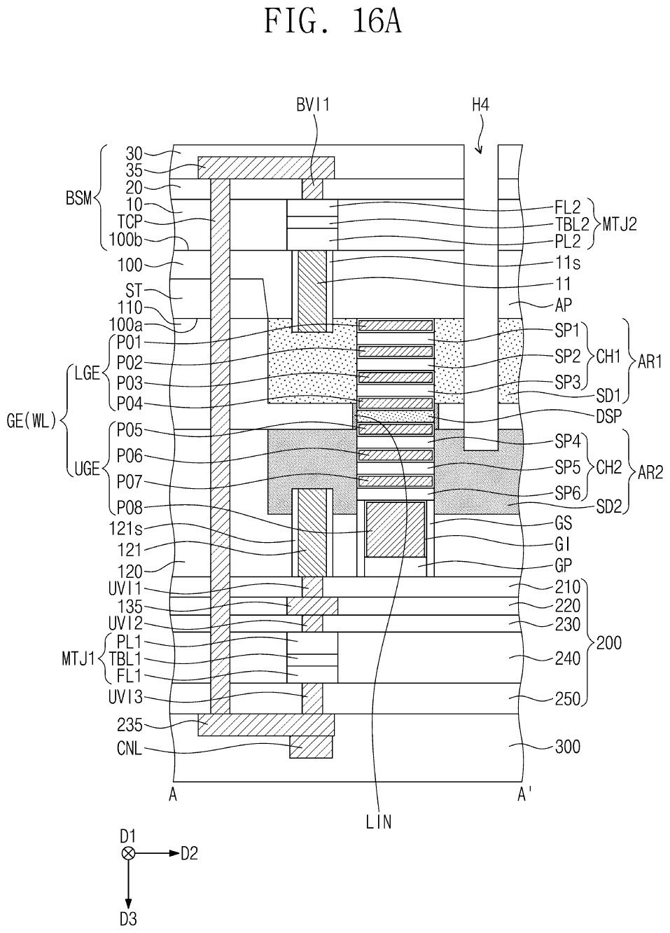

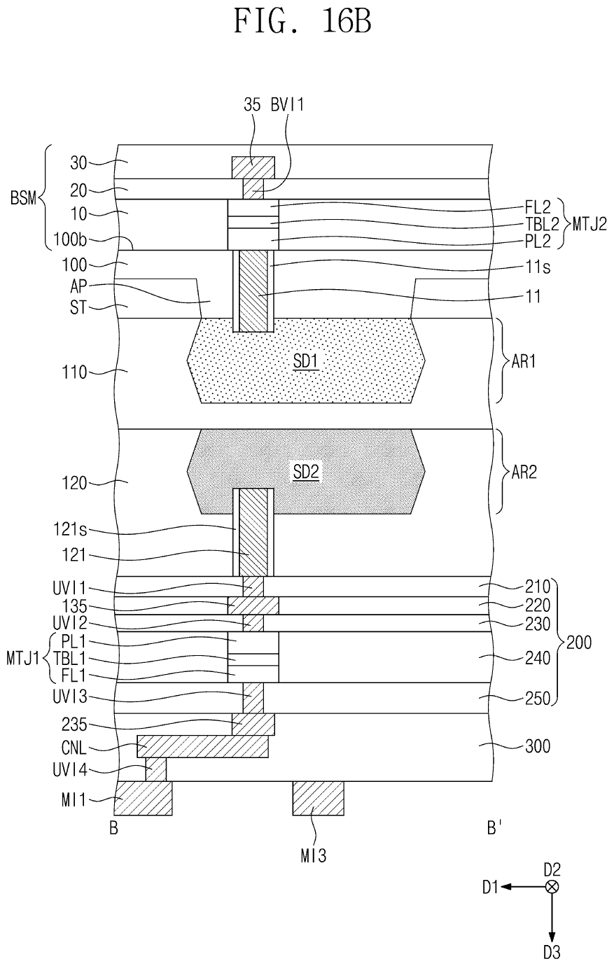

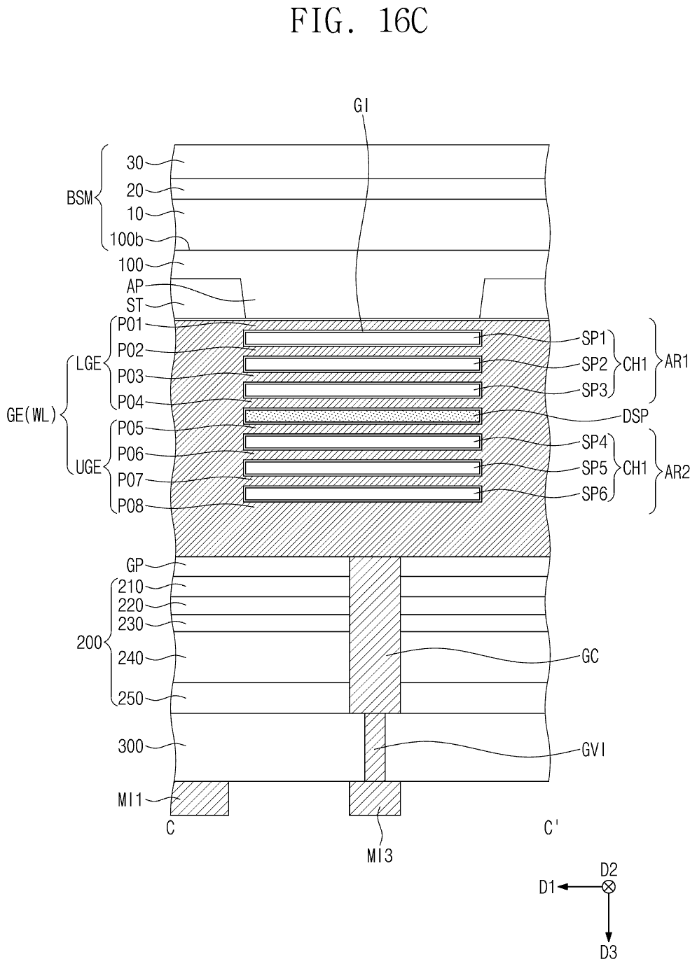

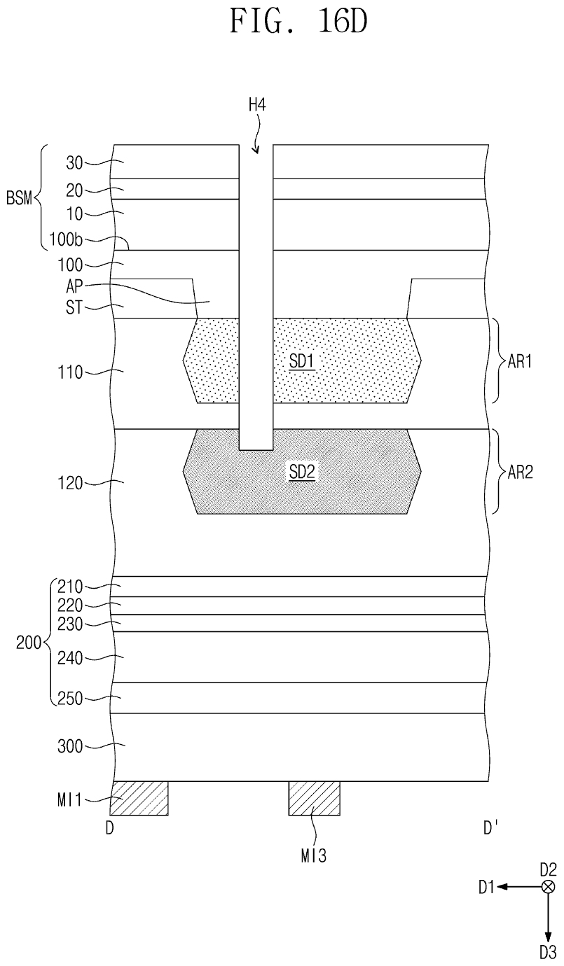

Referring to FIGS. 3 and 16A to 16D, a first lower via BVI1 that fills the via hole VH may be formed. In addition, a through-contact plug TCP that fills the third hole H3 may be formed. Forming the first lower via BVI1 and the through-contact plug TCP may include, for example, forming a conductive layer that fills the via hole VH and the third hole H3 and that may be disposed on the second lower insulating layer 20, and recessing the conductive layer until an upper surface of the second lower insulating layer 20 is exposed.

Subsequently, a lower wiring 35 may be formed on the first lower via BVI1 and the through-contact plug TCP. For example, the lower wiring 35 may be in contact with the first lower via BVI1 and the through-contact plug TCP. After the lower wiring 35 is formed, a third lower insulating layer 30 covering the second lower insulating layer 20 may be formed.

Thereafter, a fourth hole H4 may be formed that penetrates the third lower insulating layer 30, the second lower insulating layer 20, the first lower insulating layer 10, the lower source/drain pattern SD1, and the first interlayer insulating layer 110, and penetrates a portion of the upper source/drain pattern SD2. A bottom surface of the fourth hole H4 may be disposed inside the upper source/drain pattern SD2.

Referring again to FIGS. 3 and 4A to 4D, a backside contact 50 may be formed to fill the fourth hole H4. Forming the backside contact 50 may include, for example, forming a conductive layer that fills the fourth hole H4 and that may be disposed on the third lower insulating layer 30, and recessing the conductive layer until the third lower insulating layer 30 is exposed.

After forming the backside contact 50, a lower connection line BCNL and a power transmission network layer PDN may be formed. The lower connection line BCNL may be in direct contact with the backside contact 50.

The power transmission network layer PDN may include a second wiring MI2. The second wiring MI2 may be formed on the lower connection line BCNL. For example, the second wring MI2 may be in contact with the lower connection line BCNL. The second wiring MI2 may include, for example, forming a wiring line layer and patterning the wiring line layer. The second wiring MI2 may extend in the second direction D2 across the gate electrode GE. The second wiring MI2 may be connected to the backside contact 50 through the lower connection line BCNL.

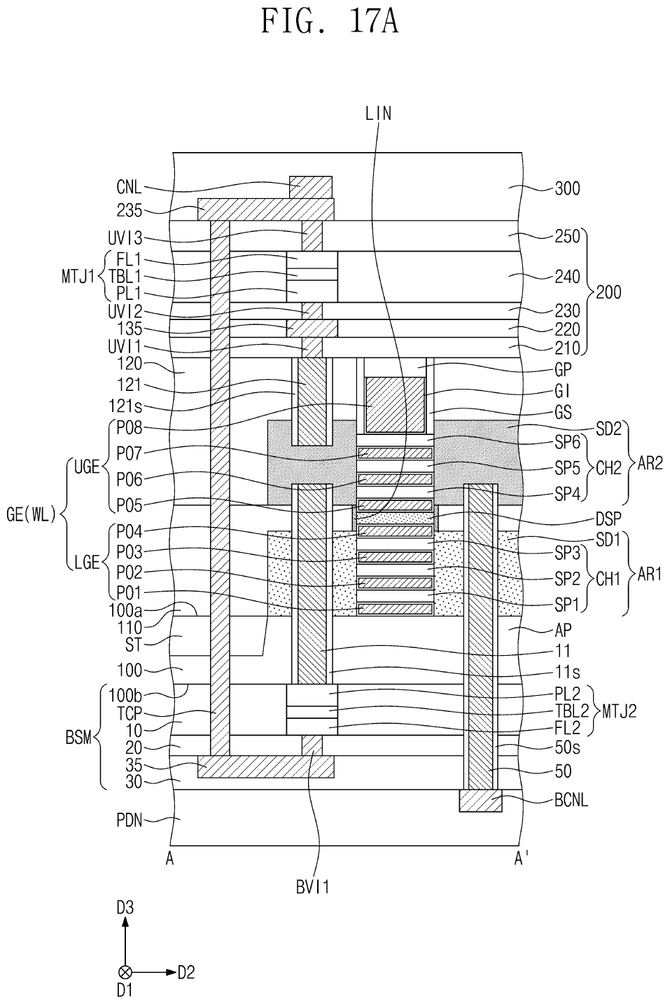

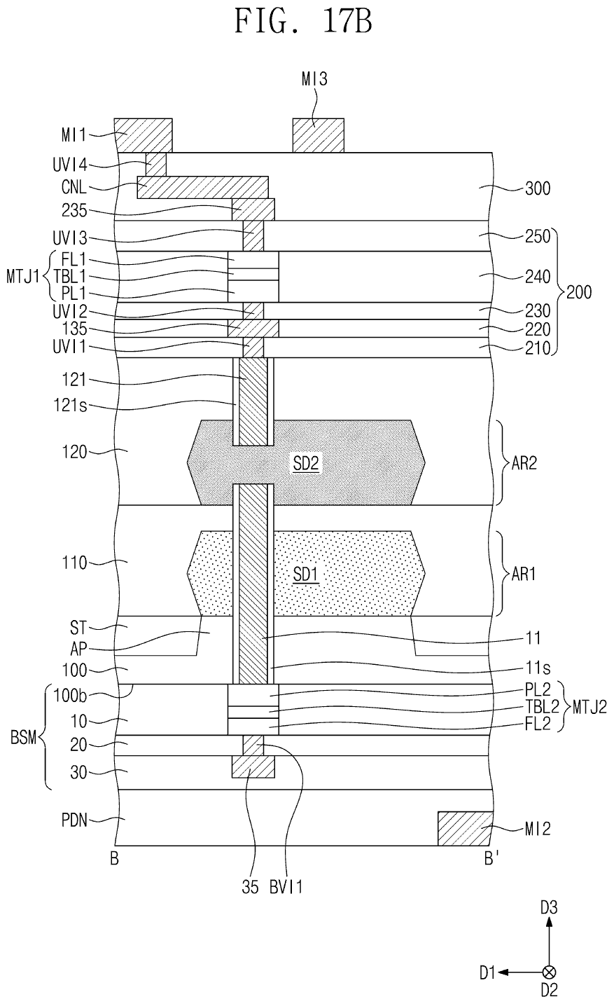

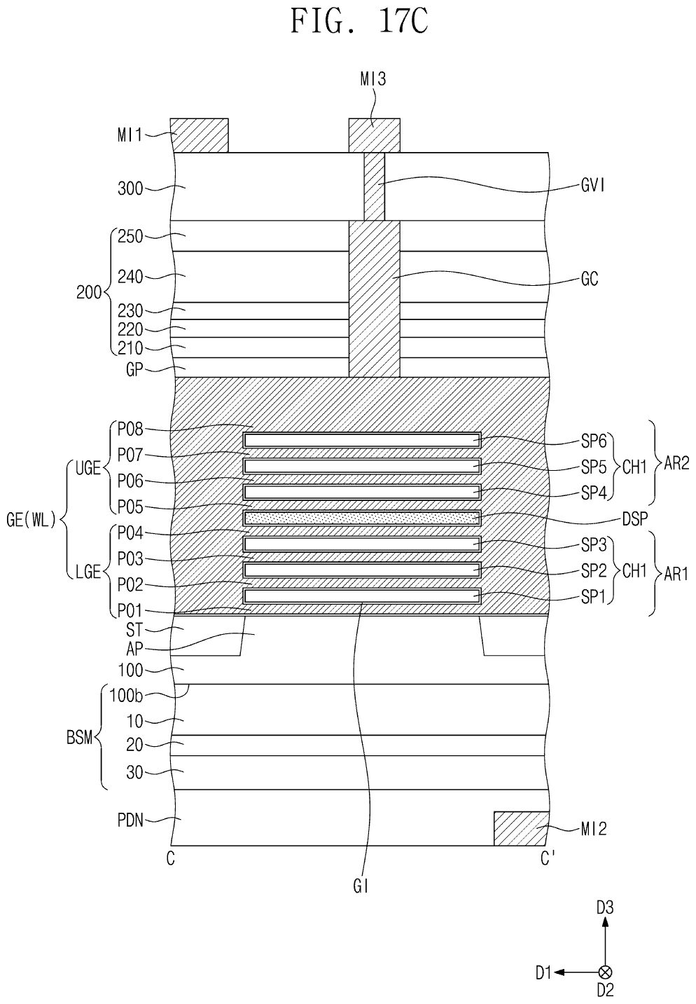

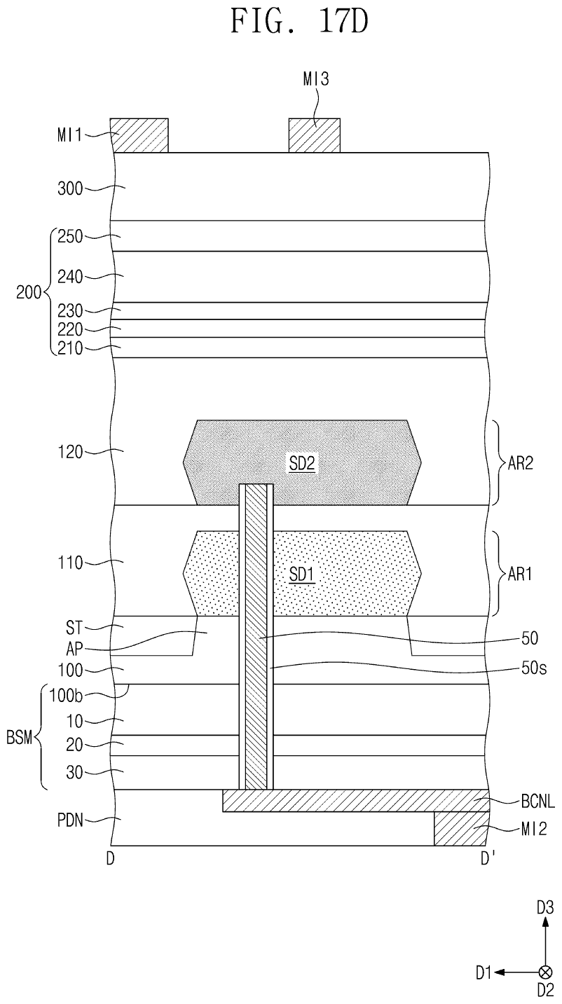

FIGS. 17A to 17D are cross-sectional views of a magnetic memory device according to embodiments of the present inventive concept, and are cross-sectional views taken along lines A-A′, B-B′, C-C′, and D-D′ of FIG. 3, respectively. For simplicity of explanation, differences from the magnetic memory device that is described with reference to FIGS. 3 and 4A to 4D will be mainly described, and redundant descriptions may be omitted or briefly discussed.

Referring to FIGS. 3 and 17A to 17D, the second active contact 11 may extend in the third direction D3 to the inside of the upper source/drain pattern SD2. The upper surface of the second active contact 11 may be disposed in the inside of the upper source/drain pattern SD2.

The lower separation structure 11s may also extend in the third direction D3 to the inside of the upper source/drain pattern SD2. The lower separation structure 11s may be interposed between the second active contact 11 and the substrate 100, between the second active contact 11 and the lower source/drain pattern SD1, between the second active contact 11 and the first interlayer insulating layer 110, and between the second active contact 11 and the upper source/drain pattern SD2. However, the lower separation structure 11s may expose the upper surface of the second active contact 11 without covering the upper surface. The second active contact 11 may be spaced apart from the lower source/drain pattern SD1 with the lower separation structure 11s interposed therebetween. The second active contact 11 might not be connected to the lower source/drain pattern SD1 because the lower separation structure 11s may electrically separate or insulate the second active contact 11 from the lower source/drain pattern SD1. For example, the second active contact 11 may be electrically connected only to the upper source/drain pattern SD2.

A backside separation structure 50s at least partially surrounding the side surface of the backside contact 50 may be provided. The backside separation structure 50s may be interposed between the backside contact 50 and the backside wiring layer BSM, between the backside contact 50 and the substrate 100, between the backside contact 50 and the lower source/drain pattern SD1, between the backside contact 50 and the first interlayer insulating layer 110, and between the backside contact 50 and the upper source/drain pattern SD2. However, the backside separation structure 50s may expose the upper surface of the backside contact 50 without covering the upper surface. The backside contact 50 may be spaced apart from the lower source/drain pattern SD1 with the backside separation structure 50s interposed therebetween. The backside contact 50 might not be connected to the lower source/drain pattern SD1 because the backside separation structure 50s may electrically separate or insulate the backside contact 50 from the lower source/drain pattern SD1. For example, the backside contact 50 may be electrically connected only to the upper source/drain pattern SD2.

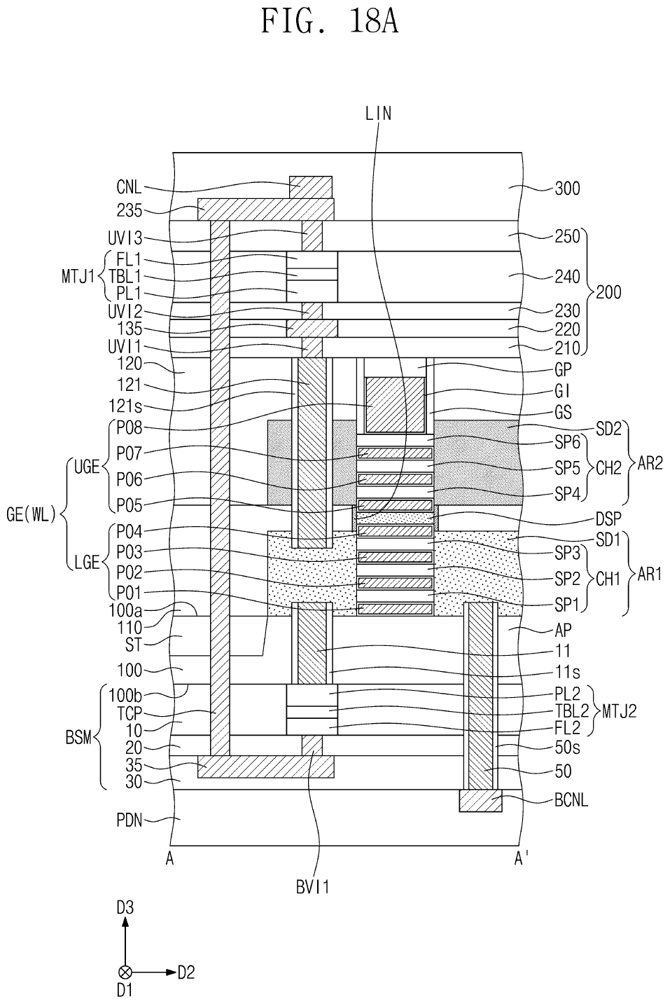

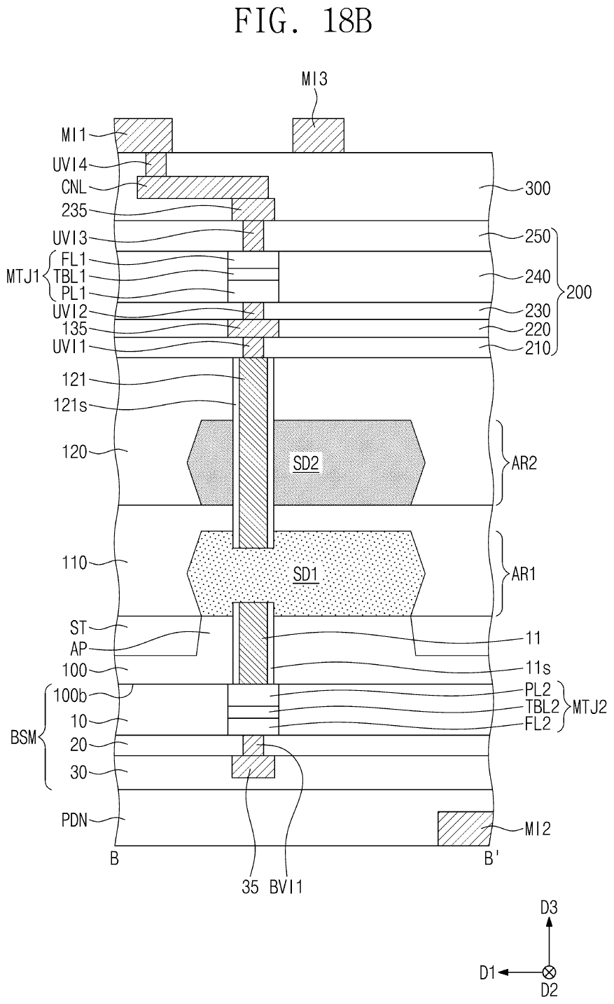

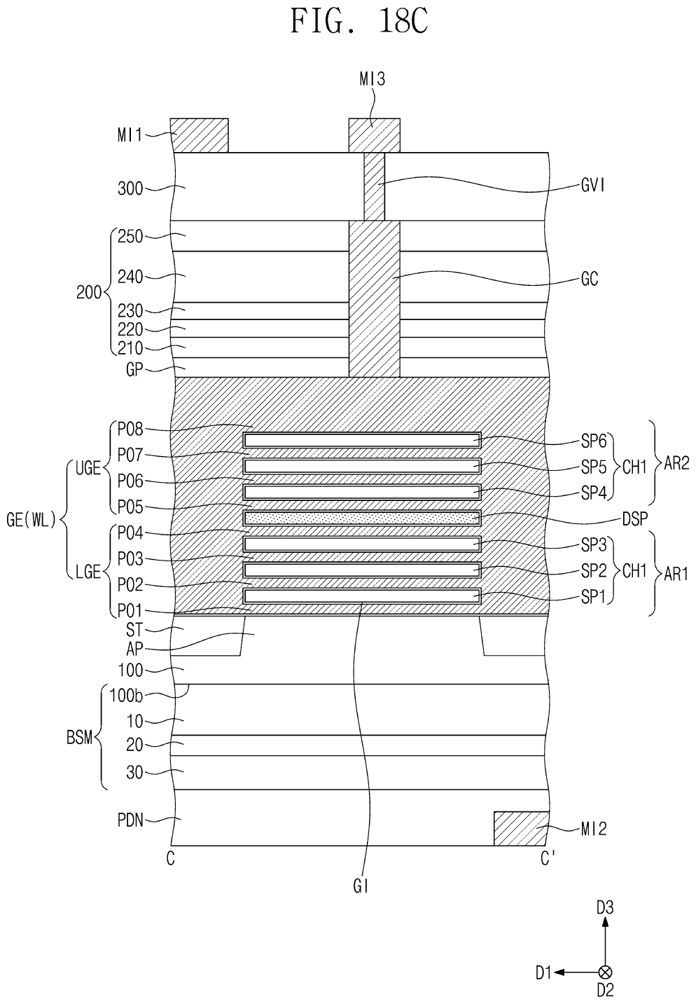

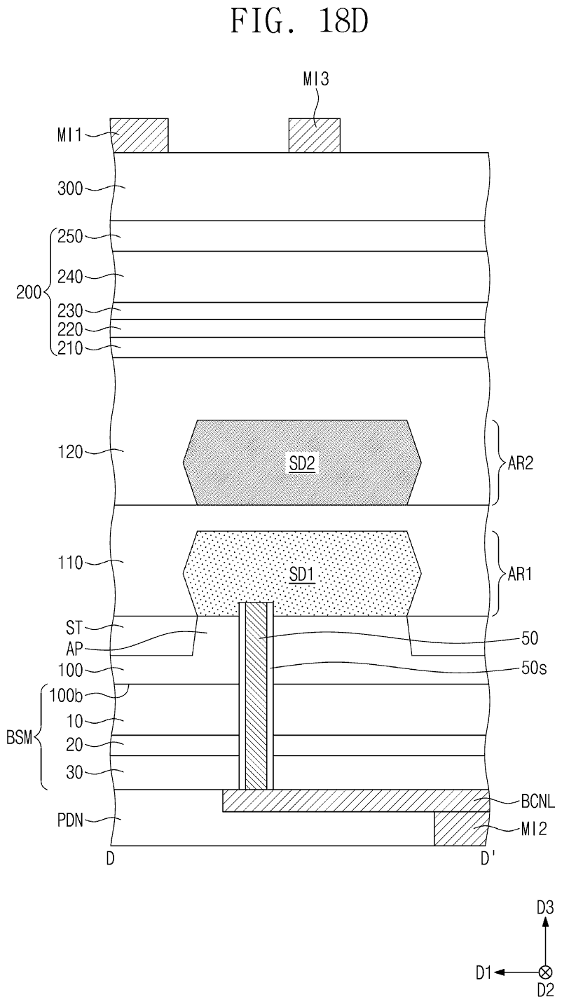

FIGS. 18A to 18D are cross-sectional views of a magnetic memory device according to embodiments of the present inventive concept, and are cross-sectional views along lines A-A′, B-B′, C-C′, and D-D′ of FIG. 3, respectively. For simplicity of explanation, differences from the magnetic memory device described with reference to FIGS. 3 and 4A to 4D will be mainly explained and redundant descriptions may be omitted or briefly discussed.

Referring to FIGS. 3 and 18A to 18D, a first active contact 121 may extend in a direction opposite to the third direction D3 to the inside of the lower source/drain pattern SD1. For example, the first active contact 121 may extend from an upper surface of the second interlayer insulating layer 120 to the inside of the lower source/drain pattern SD1. A lower surface of the first active contact 121 may be disposed inside the lower source/drain pattern SD1.

An upper separation structure 121s may also extend in the opposite direction to the third direction D3 to the inside of the lower source/drain pattern SD1. For example, the upper separation structure 121s may extend from the upper surface of the second interlayer insulating layer 120 to the inside of the lower source/drain pattern SD1. The upper separation structure 121s may be interposed between the first active contact 121 and the second interlayer insulating layer 120, between the first active contact 121 and the upper source/drain pattern SD2, between the first active contact 121 and the first interlayer insulating layer 110, and between the first active contact 121 and the lower source/drain pattern SD1. However, the upper separation structure 121s may expose the lower surface of the first active contact 121 without covering the lower surface of first active contact 121. The first active contact 121 may be separated from the upper source/drain pattern SD2 with the upper separation structure 121s therebetween. The first active contact 121 might not be connected to the upper source/drain pattern SD2 because the upper separation structure 121s may electrically separate or insulate the first active contact 121 from the upper source/drain pattern SD2. For example, the first active contact 121 may be electrically connected only to the lower source/drain pattern SD1.

A backside contact 50 may extend into the interior of the lower source/drain pattern SD1 by penetrating the backside wiring layer BSM and the substrate 100. An upper surface of the backside contact 50 may be disposed inside the lower source/drain pattern SD1.

A backside separation structure 50s that at least partially surrounds a side surface of the backside contact 50 may be provided. The backside separation structure 50s may be interposed between the backside contact 50 and the backside wiring layer BSM, between the backside contact 50 and the substrate 100, and between the backside contact 50 and the lower source/drain pattern SD1. However, the backside separation structure 50s may expose the upper surface of the backside contact 50 without covering the upper surface of backside contact 50. In embodiments of the present inventive concept, the backside separation structure 50s may be omitted.

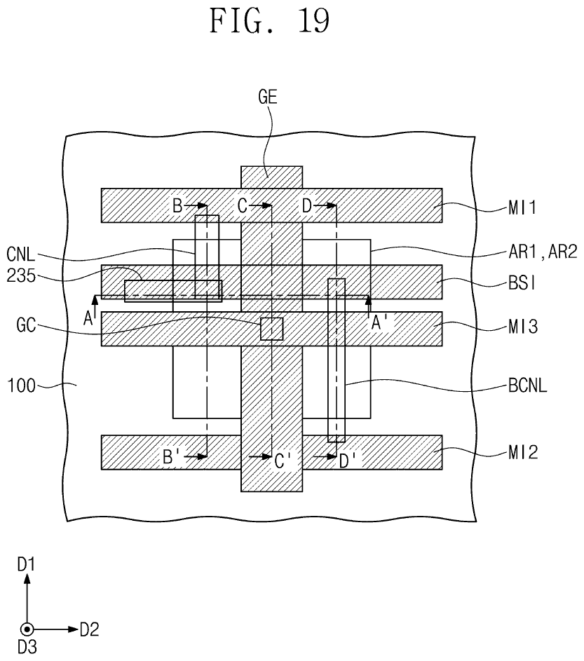

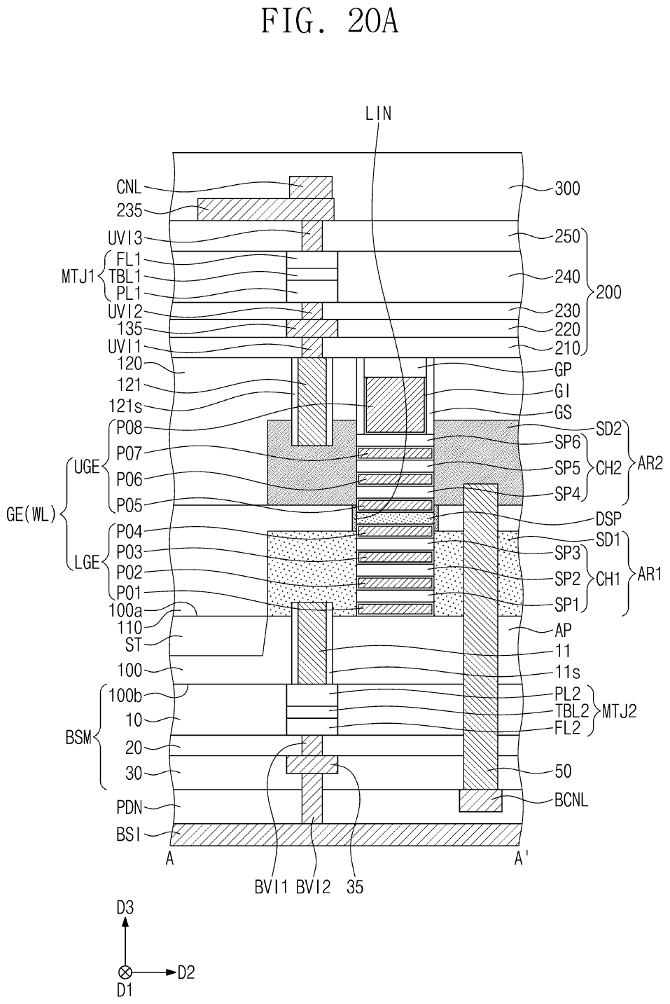

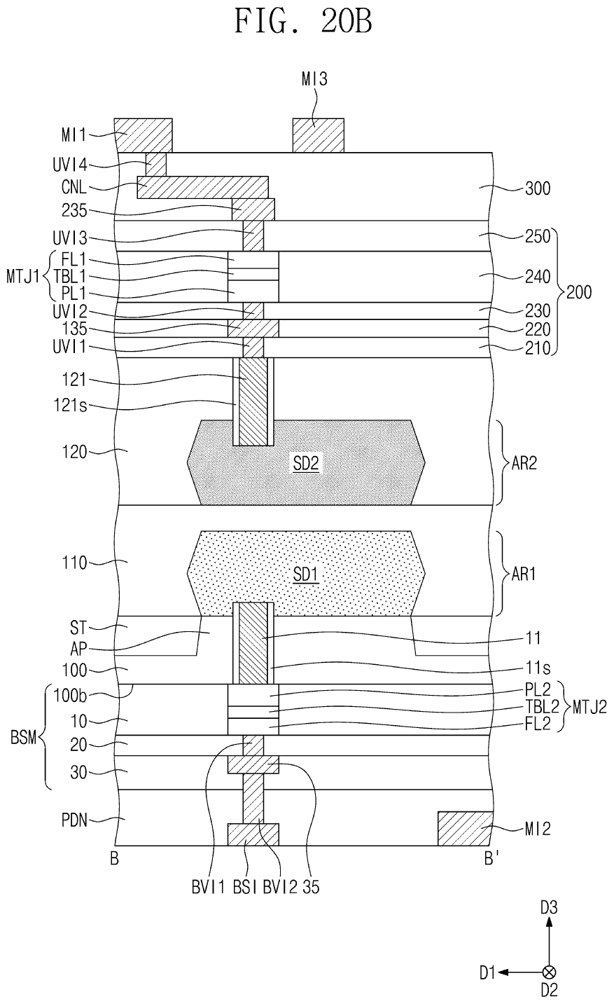

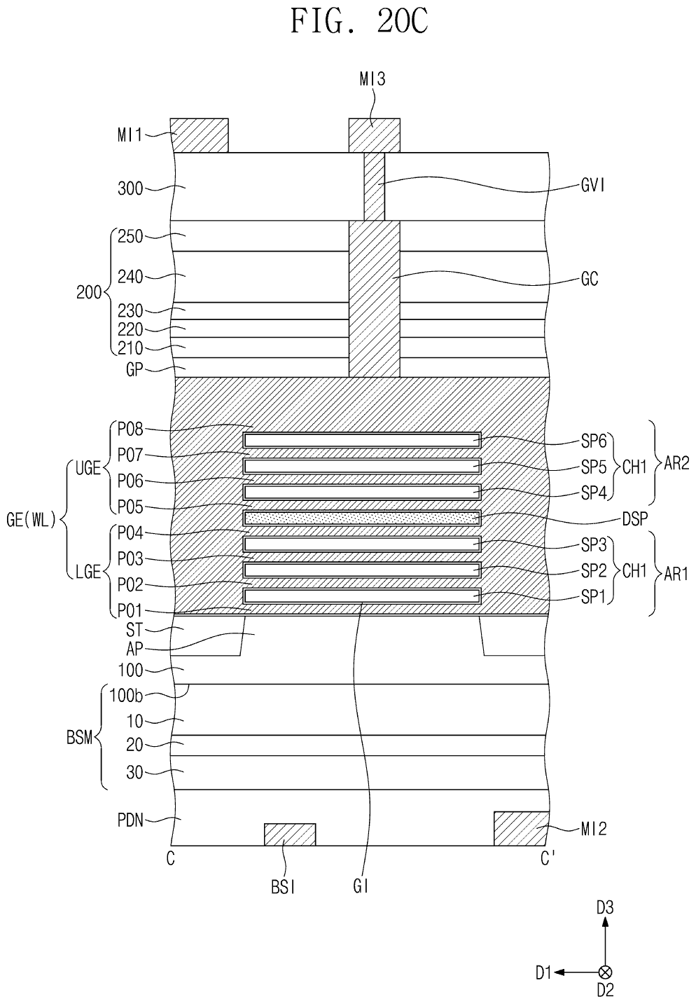

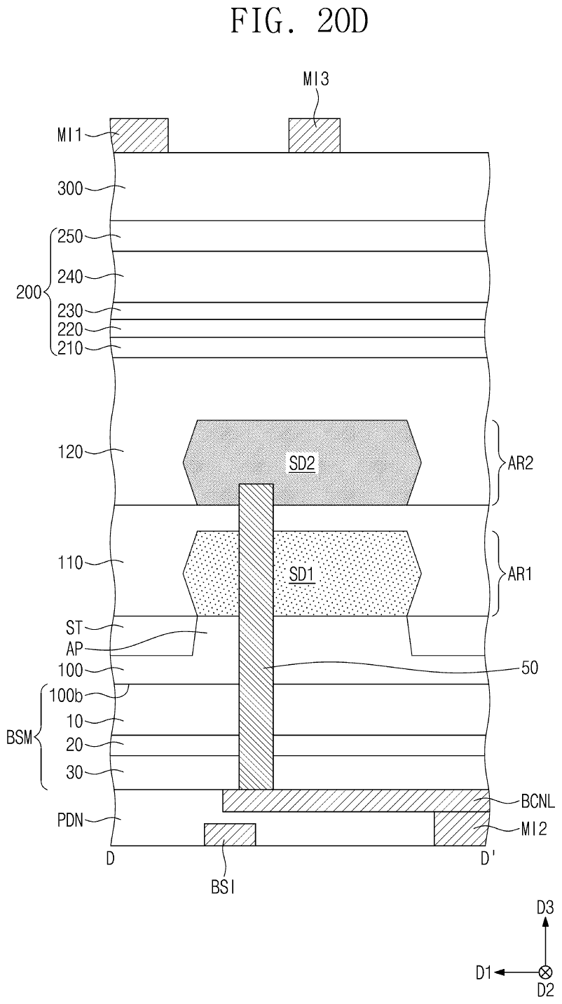

FIG. 19 is a plan view of a magnetic memory device according to embodiments of the present inventive concept. FIGS. 20A to 20D are cross-sectional views of a magnetic memory device according to embodiments of the present inventive concept, and are cross-sectional views taken along lines A-A′, B-B′, C-C′, and D-D′ of FIG. 19, respectively. For simplicity of explanation, differences from the magnetic memory device described with reference to FIGS. 3 and 4A to 4D will be mainly described, and redundant descriptions may be omitted or briefly discussed.

Referring to FIGS. 19 and 20A to 20D, a backside power wiring BSI may be provided in the power transmission network layer PDN. A backside power wiring BSI may extend in a second direction D2 across the gate electrode GE. A second lower via BVI2 may be provided between the backside power wiring BSI and the lower wiring 35. For example, the upper and lower surfaces of the second lower via BVI2 may be in contact with the lower wiring 35 and the backside power wiring BSI, respectively. That is, the backside power wiring BSI may be electrically connected to the second magnetic tunnel junction pattern MTJ2 through the second lower via BVI2, the lower wiring 35, and the first lower via BVI1. In addition, a backside power wiring BSI may be electrically connected to a lower source/drain pattern SD1 through the second active contact 11.

Compared with the magnetic memory device of the above-described FIGS. 4A to 4D, the magnetic memory device according to the embodiment of FIGS. 20A to 20D might not include a through-contact plug TCP. For example, the lower source/drain pattern SD1 may be electrically connected to the backside power wiring BSI, and the upper source/drain pattern SD2 may be electrically connected to the first wiring MI1.

According to embodiments of the present inventive concept, by forming the main cell and the OTP cell on the front and back surfaces 100a and 100b of the substrate 100, the wiring of the main cell and the OTP cell may be separately formed, thereby increasing stability of a main cell.

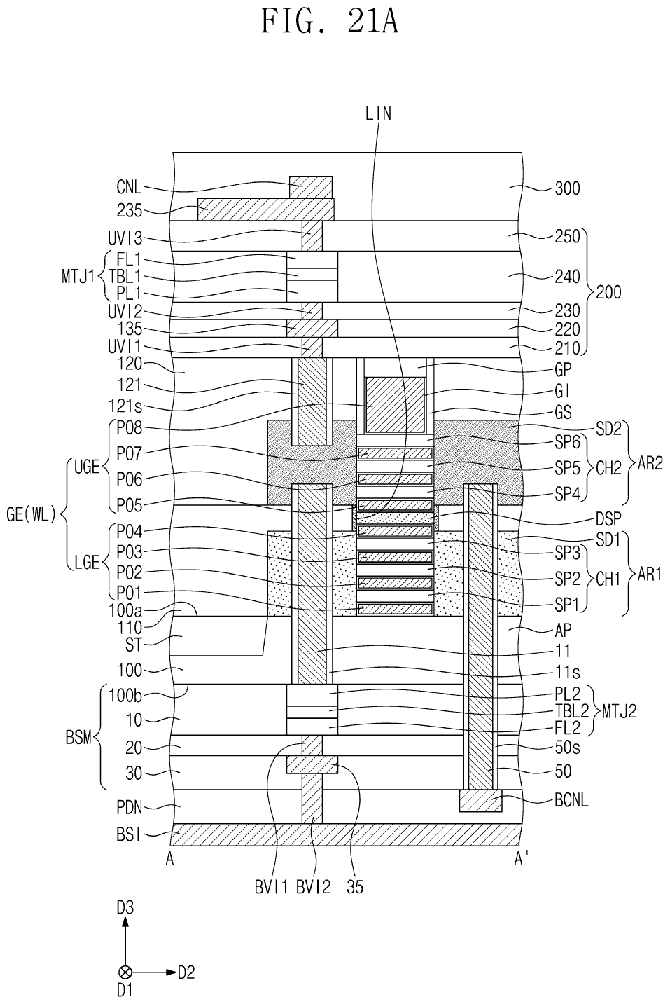

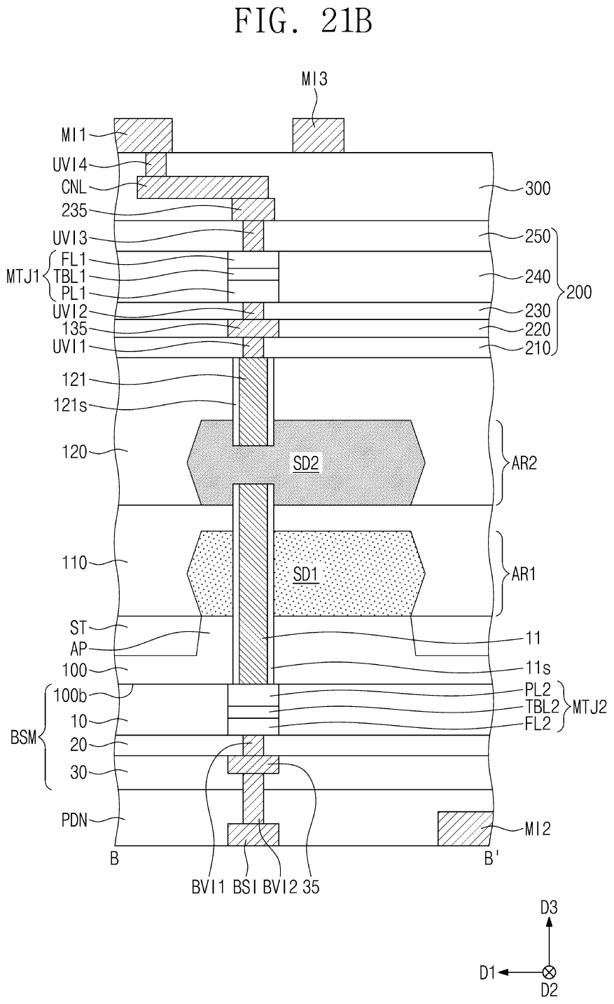

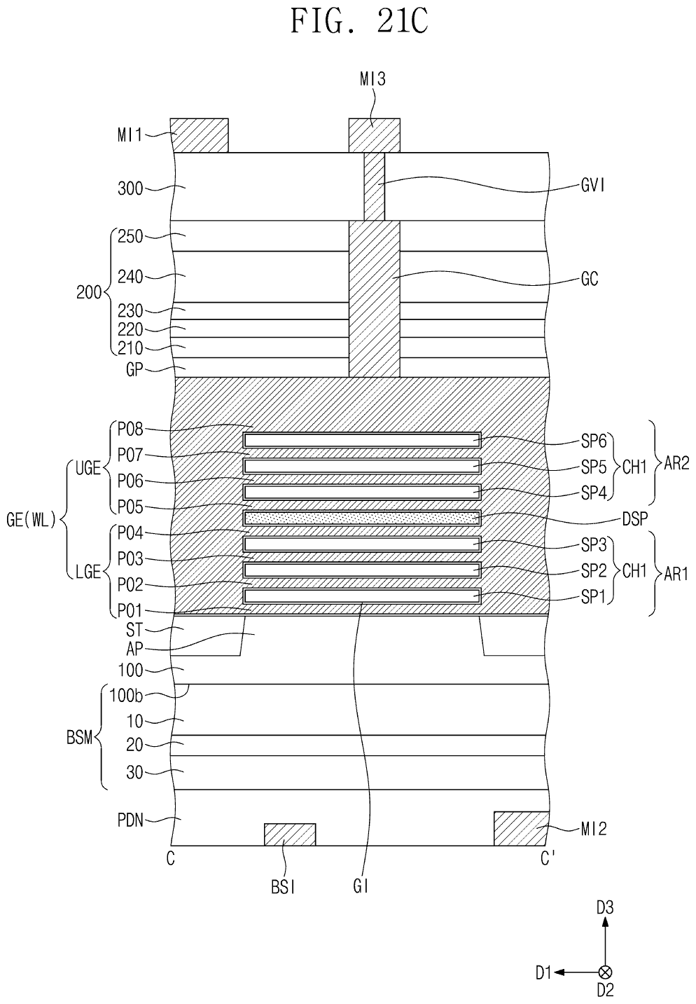

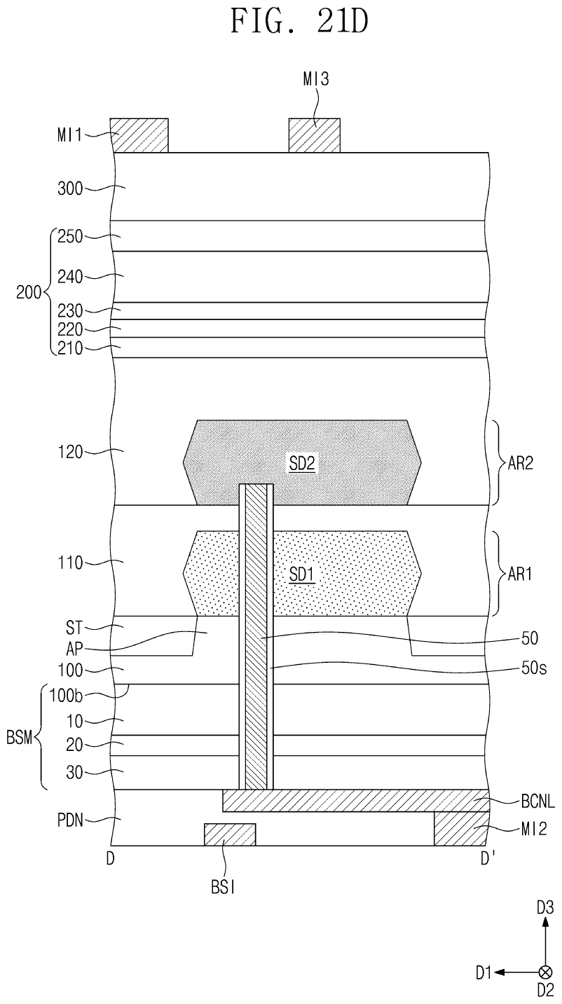

FIGS. 21A to 21D are cross-sectional views of the magnetic memory device according to embodiments of the present inventive concept, and are cross-sectional views along the lines A-A′, B-B′, C-C′, and D-D′ of FIG. 19, respectively. For simplicity of explanation, the differences from the magnetic memory device described with reference to FIGS. 3 and 4A to 4D will be mainly explained and redundant descriptions may be omitted or briefly discussed.

Referring to FIGS. 19 and 21A to 21D, the second active contact 11 may extend in the third direction D3 to the inside of the upper source/drain pattern SD2. An upper surface of the second active contact 11 may be disposed in the inside of the upper source/drain pattern SD2.

The lower separation structure 11s may also extend in the third direction D3 to the inside of the upper source/drain pattern SD2. The second active contact 11 might not be connected to the lower source/drain pattern SD1 because the lower separation structure 11s may electrically separate or insulate the second active contact 11 from the lower source/drain pattern SD1.

A backside separation structure 50s surrounding a side surface of the backside contact 50 may be provided. The backside contact 50 might not be connected to the lower source/drain pattern SD1 because the backside separation structure 50s may electrically separate or insulate the backside contact 50 from the lower source/drain pattern SD1.

A backside power wiring BSI may be provided in the power transmission network layer PDN. A second lower via BVI2 may be provided between the backside power wiring BSI and the lower wiring 35. The backside power wiring BSI may be electrically connected to the second magnetic tunnel junction pattern MTJ2 through the second lower via BVI2, the lower wiring 35, and the first lower via BVI1. In addition, the backside power wiring BSI may be electrically connected to the lower source/drain pattern SD1 through the second active contact 11.

Compared with the magnetic memory devices of FIGS. 4A to 4D described above, the magnetic memory devices according to the embodiments of FIGS. 21A to 21D might not include a through-hole contact plug TCP. That is, the upper source/drain pattern SD2 may be electrically connected to the backside power wiring BSI and the first wiring MI1 through the second active contact 11 penetrating the substrate 100 and the lower source/drain pattern SD1.

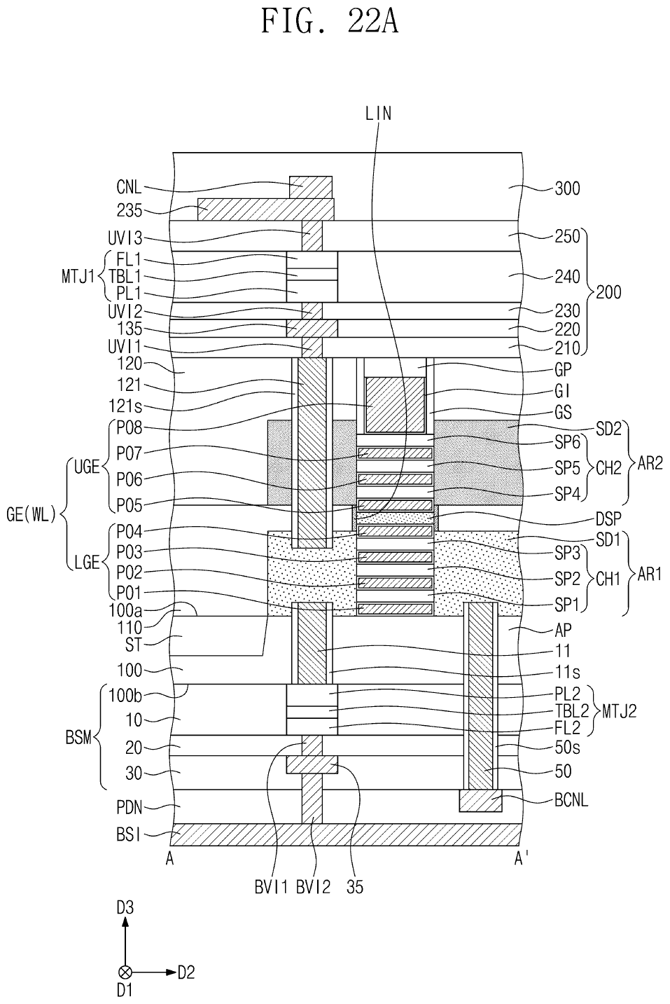

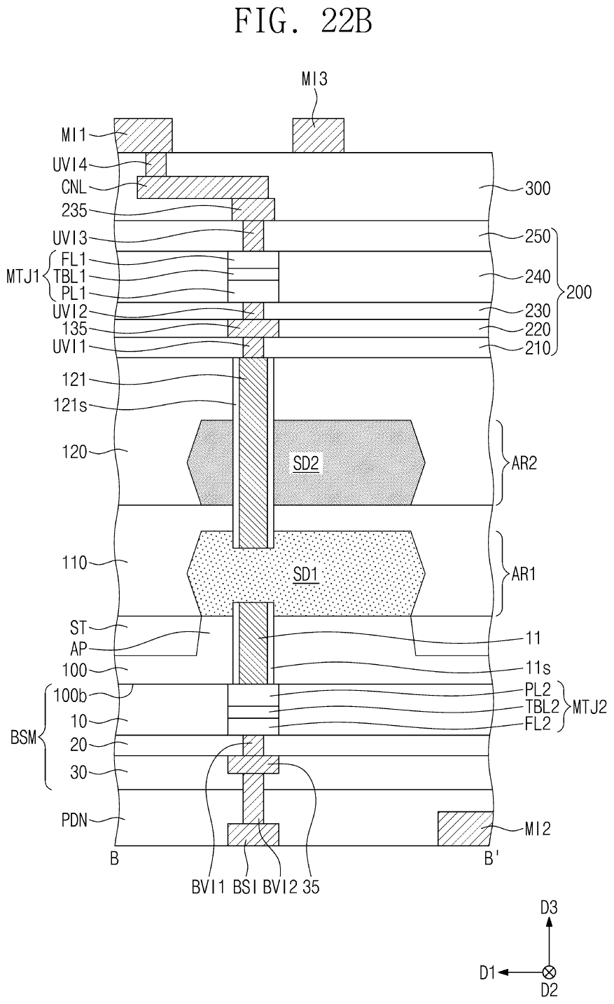

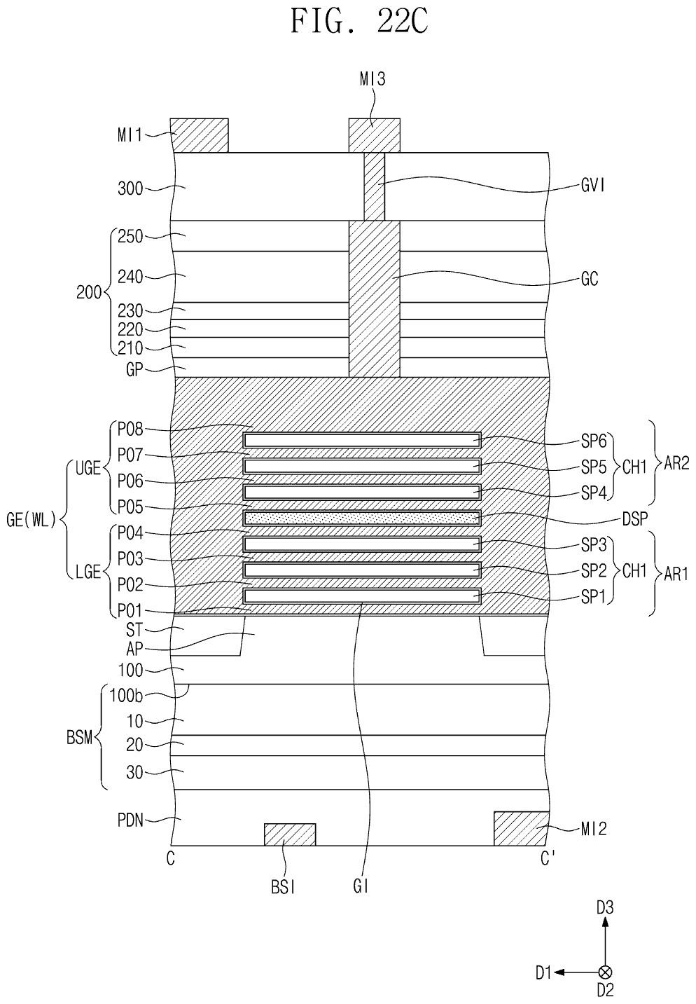

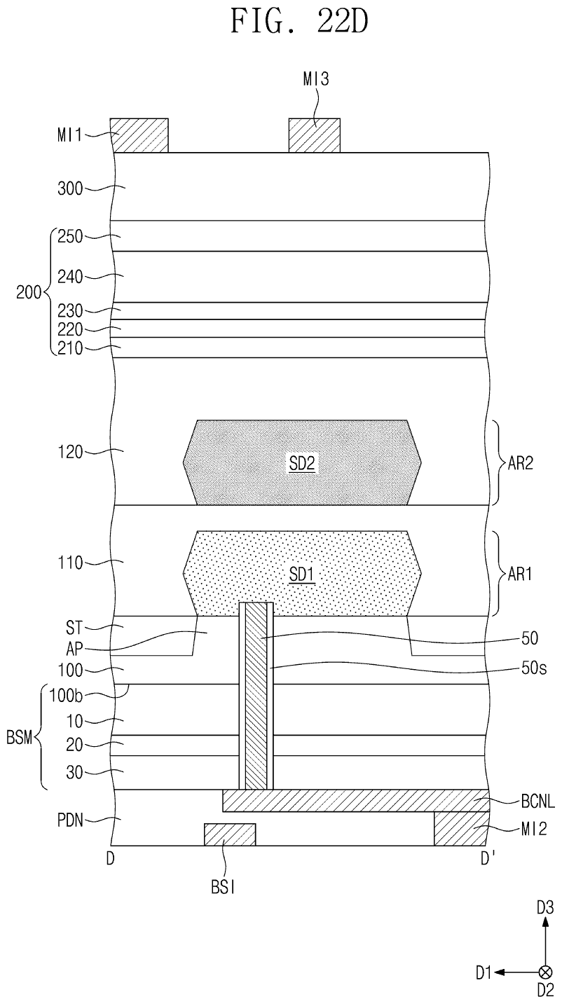

FIGS. 22A to 22D are cross-sectional views of a magnetic memory device according to embodiments of the present inventive concept, and are cross-sectional views taken along lines A-A′, B-B′, C-C′, and D-D′ of FIG. 19, respectively. For simplicity of explanation, differences from the magnetic memory device described with reference to FIGS. 3 and 4A to 4D will be mainly described and redundant descriptions may be omitted or briefly discussed.

Referring to FIGS. 19 and 22A to 22D, the first active contact 121 may extend in a direction opposite to the third direction D3 to the inside of the lower source/drain pattern SD1. For example, the first active contact 121 may extend from the upper surface of the second interlayer insulating layer 120 to the inside of the lower source/drain pattern SD1. The lower surface of the first active contact 121 may be disposed in the inside of the lower source/drain pattern SD1. For example, the first active contact 121 may be electrically connected to the lower source/drain pattern SD1.

The upper separation structure 121s may also extend in a direction opposite to the third direction D3 to the inside of the lower source/drain pattern SD1. The first active contact 121 might not be connected to the upper source/drain pattern SD2 because the separation structure 121s may electrically separate or insulate the first active contact 121 from the upper source/drain pattern SD2.

The backside contact 50 may be provided that extends into the interior of the lower source/drain pattern SD1 by penetrating the backside wiring layer BSM and the substrate 100. An upper surface of the backside contact 50 may be disposed inside the lower source/drain pattern SD1. The backside contact 50 may be electrically connected to the lower source/drain pattern SD1.

A backside separation structure 50s surrounding a side surface of the backside contact 50 may be provided. The backside separation structure 50s may be interposed between the backside contact 50 and the backside wiring layer BSM, between the backside contact 50 and the substrate 100, and between the backside contact 50 and the lower source/drain pattern SD1. However, an upper surface of the backside contact 50 may be exposed by the backside separation structure 50s. Unlike as illustrated, the backside separation structure 50s may be omitted.

A backside power wiring BSI may be provided in the power transmission network layer PDN. A second lower via BVI2 may be provided between the backside power wiring BSI and the lower wiring 35. The backside power wiring BSI may be electrically connected to the second magnetic tunnel junction pattern MTJ2 through the second lower via BVI2, the lower wiring 35, and the first lower via BVI1. In addition, the backside power wiring BSI may be electrically connected to the lower source/drain pattern SD1 through the second active contact 11, which is electrically connected to the second magnetic tunnel junction pattern MTJ2.

Compared with the magnetic memory device of FIGS. 4A to 4D described above, the magnetic memory device according to the embodiment of FIGS. 22A to 22D might not include a through-contact plug TCP. That is, the lower source/drain pattern SD1 may be electrically connected to the backside power wiring BSI and the first wiring MI1.

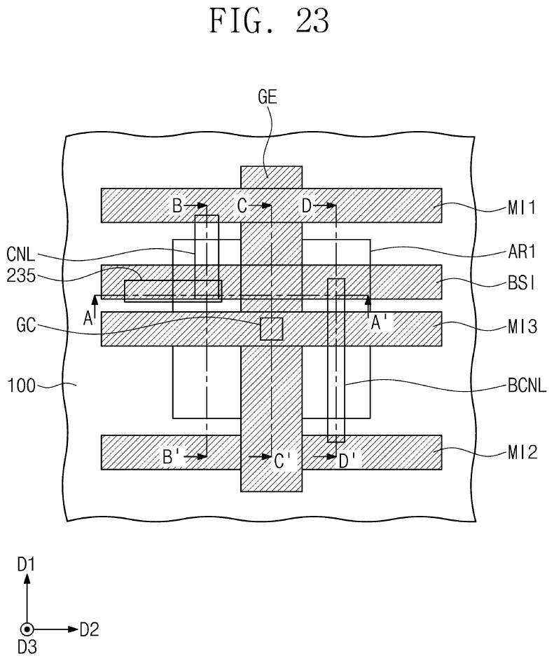

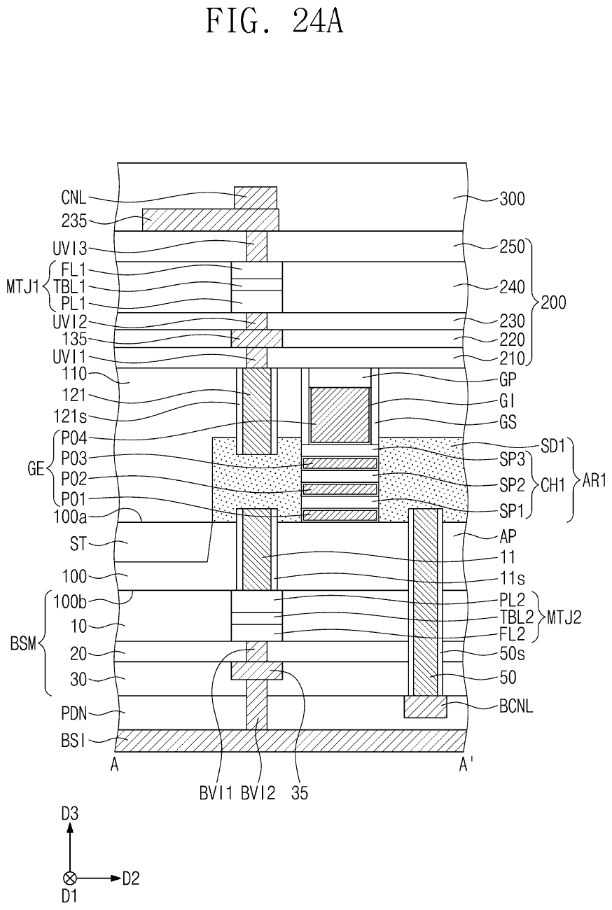

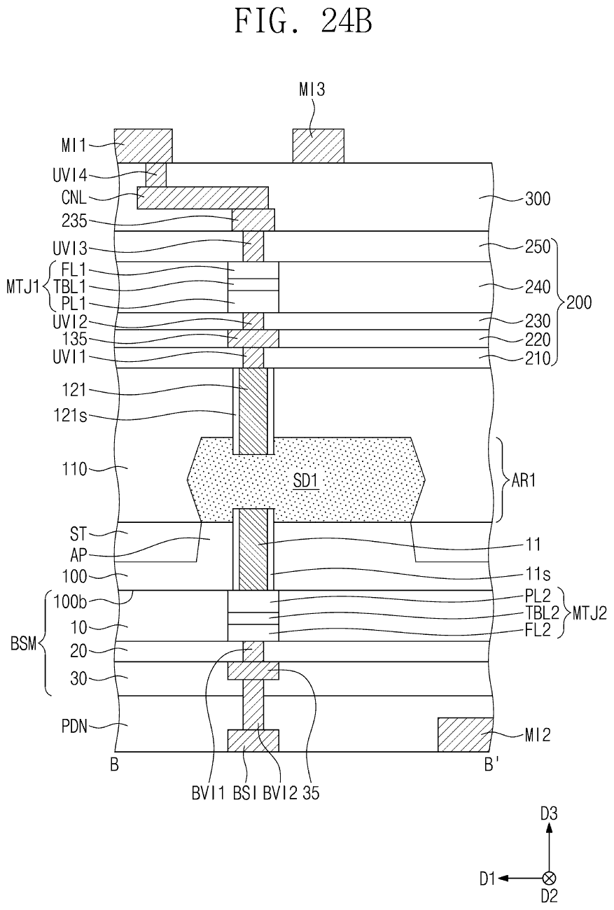

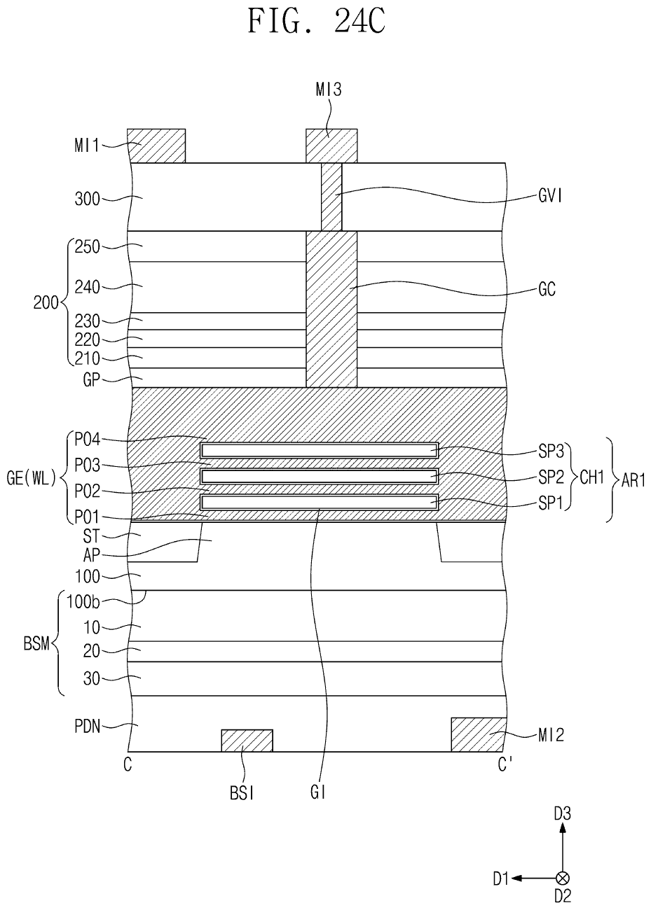

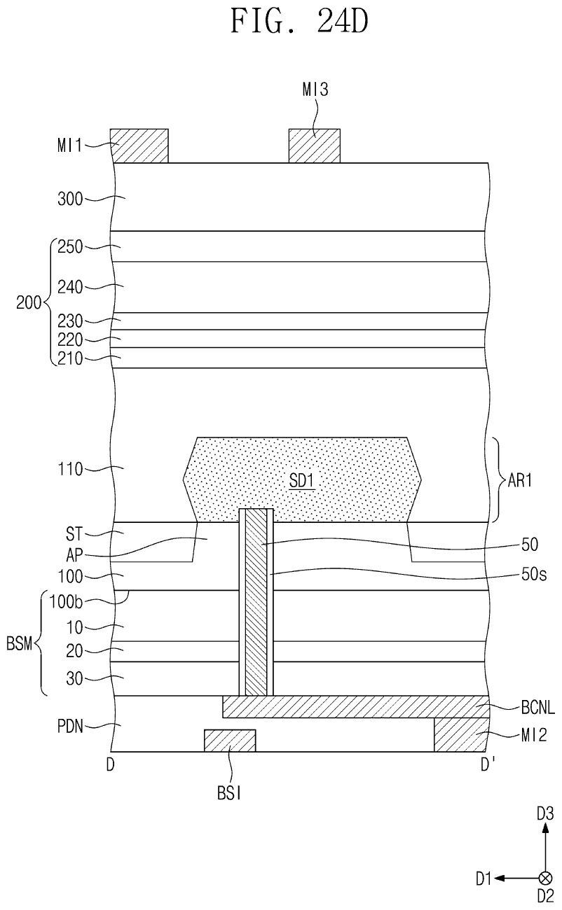

FIG. 23 is a plan view of a magnetic memory device according to embodiments of the present inventive concept. FIGS. 24A to 24D are cross-sectional views of a magnetic memory device according to embodiments of the present inventive concept, taken along lines A-A′, B-B′, C-C′, and D-D′ of FIG. 23, respectively. For simplicity of explanation, differences from the magnetic memory device described with reference to FIGS. 3 and 4A to 4D will be mainly described and redundant descriptions may be omitted or briefly discussed.

Referring to FIGS. 23 and 24A to 24D, compared to the magnetic memory device of FIGS. 4A to 4D, the dummy channel pattern DSP, the upper source/drain pattern SD2, the upper channel pattern CH2, the second active region AR2, the upper gate electrode UGE, and the second interlayer insulating layer 120 might not be provided.

A first active region AR1 may be disposed on the active pattern AP of the substrate 100. The first active region AR1 may include a lower channel pattern CH1 and lower source/drain patterns SD1. The lower channel pattern CH1 and the lower source/drain patterns SD1 may include substantially the same configuration as described above with reference to FIGS. 4A to 4D.

A gate electrode GE may be disposed on the lower channel pattern CH1. The gate electrode GE may vertically overlap with the lower channel patterns CH1. The gate electrode GE may be provided on an upper surface, a bottom surface, and both sidewalls of each of the first to third semiconductor patterns SP1 to SP3. In other words, the transistor according to the present embodiment may include a three-dimensional field effect transistor (e.g., MBCFET or GAAFET) in which the gate electrode GE surrounds the channel three-dimensionally.

The gate electrode GE may include a first portion PO1 interposed between the active pattern AP and the first semiconductor pattern SP1, a second portion PO2 interposed between the first semiconductor pattern SP1 and the second semiconductor pattern SP2, a third portion PO3 interposed between the second semiconductor pattern SP2 and the third semiconductor pattern SP3, and a fourth portion PO4 on the third semiconductor pattern SP3.

Gate spacers GS may be respectively disposed on both sidewalls of the gate electrode GE. Referring to FIG. 24A, the gate spacers GS may be respectively disposed on both sidewalls of the fourth portion PO4. Upper surfaces of the gate spacers GS may be substantially coplanar or coplanar with an upper surface of the first interlayer insulating layer 110.

A gate capping pattern GP may be provided on an upper surface of the gate electrode GE. The gate capping pattern GP may extend in the first direction D1 along the gate electrode GE.

A gate insulating layer GI may be interposed between the gate electrode GE and the first to third semiconductor patterns SP1 to SP3. The gate insulating layer GI may include the same material as described above with reference to FIGS. 4A to 4D.

An upper insulating layer 200 may be disposed on the first interlayer insulating layer 110. The upper insulating layer 200 may cover the gate spacers GS and the gate capping pattern GP.

A first active contact 121 electrically connected to the lower source/drain pattern SD1 may be disposed. The first active contact 121 may extend from an upper surface of the first interlayer insulating layer 110 through a portion of the first interlayer insulating layer 110 into the interior of the lower source/drain pattern SD1. A lower surface of the first active contact 121 may be disposed in the lower source/drain pattern SD1.

An upper separation structure 121s surrounding a side surface of the first active contact 121 may be disposed. The upper separation structure 121s may be interposed between the first active contact 121 and the upper source/drain patterns SD2 and may extend in the third direction D3. In embodiments of the present inventive concept, the upper separation structure 121s may be omitted.

The upper insulating layer 200 may include a first upper insulating layer 210, a second upper insulating layer 220, a third upper insulating layer 230, a fourth upper insulating layer 240, and a fifth upper insulating layer 250 that are sequentially stacked. A gate contact GC, first to third upper vias UVI1 to UVI3, an interlayer wiring 135, and a first magnetic tunnel junction pattern MTJ1 may be disposed in the upper insulating layer 200. The gate contact GC, the first to third upper vias UVI1 to UVI3, the interlayer wiring 135, and the first magnetic tunnel junction pattern MTJ1 disposed in the upper insulating layer 200 and the upper insulating layer 200 may have substantially the same configuration as described above with reference to FIGS. 4A to 4D.

A wiring insulating layer 300 may be disposed on the upper insulating layer 200. A gate via GVI, an upper wiring 235, an upper connection line CNL, and a fourth upper via UVI4 may be disposed in the wiring insulating layer 300. The wiring insulating layer 300 and the gate via GVI, the upper wiring 235, the upper connection line CNL, and the fourth upper via UVI4 in the wiring insulating layer 300 may have substantially the same configuration as described above with reference to FIGS. 4A to 4D.

A first wiring MI1 and a third wiring MI3 may be disposed on the wiring insulating layer 300. The first wiring MI1 and the third wiring MI3 may also have substantially the same configuration as the first and third wirings MI1 and MI3 described above with reference to FIGS. 4A to 4D.

A second active contact 11 electrically connected to the lower source/drain pattern SD1 may be disposed. The second active contact 11 may extend from the back surface 100b of the substrate 100 through the substrate 100 into the interior of the lower source/drain pattern SD1. An upper surface of the second active contact 11 may be disposed in the lower source/drain pattern SD1.

A lower separation structure 11s at least partially surrounding the second active contact 11 may be disposed. The lower separation structure 11s may be interposed between the second active contact 11 and the lower source/drain patterns SD1 and may extend in the third direction D3. In embodiments of the present inventive concept, the lower separation structure 11s may be omitted.

A backside wiring layer BSM may be disposed on the back surface 100b of the substrate 100. A power transmission network layer PDN may be disposed on the backside wiring layer BSM.

A second magnetic tunnel junction pattern MTJ2, a first lower via BVI1, and a lower wiring 35 may be disposed in the backside wiring layer BSM. The backside wiring layer BSM and the second magnetic tunnel junction pattern MTJ2, the first lower via BVI1, and the lower wiring 35 in the backside wiring layer BSM may have substantially the same configuration as described above with reference to FIGS. 4A to 4D.

A backside contact 50 may be provided that penetrates the backside wiring layer BSM, the substrate 100, and extends into the interior of the lower source/drain pattern SD1. An upper surface of the backside contact 50 may be disposed in the interior of the lower source/drain pattern SD1.

A backside separation structure 50s surrounding the side surface of the backside contact 50 may be provided. The backside separation structure 50s may be interposed between the backside contact 50 and the backside wiring layer BSM, the substrate 100, and the lower source/drain pattern SD1. However, the backside separation structure 50s may expose the upper surface of the backside contact 50 without covering the backside contact 50. Unlike the drawing, the backside separation structure 50s may be omitted.

A lower connection line BCNL and a second wiring MI2 may be provided in the power transmission network layer PDN. The lower connection line BCNL and the second wiring MI2 may include substantially the same configuration as described above with reference to FIGS. 4A to 4D.

A backside power wiring BSI may be provided in the power transmission network layer PDN. A second lower via BVI2 may be provided between the backside power wiring BSI and the lower wiring 35. The backside power wiring BSI and the second lower via BVI2 may include substantially the same configuration as described above with reference to FIGS. 22A to 22D.

According to embodiments of the present inventive concept, the OTP cell and the main cell may be disposed on the front surface and back surface of the substrate, respectively, and thus, the OTP cell area might not be allocated separately and the cell area may be reduced. Accordingly, the integration of the magnetic memory device may be increased.

In addition, the wiring may be formed on the back surface of the substrate, thereby reducing the wiring complexity.

In addition, the stability of the main cell may be increased.

While the present inventive concept has been described with reference to embodiments thereof, it will be understood by those of ordinary skill in the art that various changes in form and details may be made thereto without departing from the spirit and scope of the present inventive concept.

What is claimed is:

1. A magnetic memory device comprising:
a substrate having upper and lower surfaces facing each other;
a first active region disposed on the upper surface of the substrate, wherein the first active region includes a lower channel pattern and a lower source/drain pattern connected to the lower channel pattern;
a second active region stacked on the first active region, wherein the second active region includes an upper channel pattern and an upper source/drain pattern connected to the upper channel pattern;
an interlayer insulating layer covering the lower and upper source/drain patterns;
a first active contact extending from an upper surface of the interlayer insulating layer to be disposed on the upper source/drain pattern;
an upper insulating layer disposed on the interlayer insulating layer;
a first magnetic tunnel junction pattern disposed in the upper insulating layer, wherein the first magnetic tunnel junction pattern is connected to the first active contact through an interlayer wiring;
a backside wiring layer disposed on the lower surface of the substrate;
a second magnetic tunnel junction pattern disposed in the backside wiring layer; and
a second active contact extending from the lower surface of the substrate to be disposed on the lower source/drain pattern,
wherein the second active contact is connected to the second magnetic tunnel junction pattern.

2. The magnetic memory device of claim 1, further comprising a backside contact penetrating the backside wiring layer, the substrate, and the lower source/drain pattern and disposed on the upper source/drain pattern.

3. The magnetic memory device of claim 1, further including:
an upper wiring disposed on the upper insulating layer;
an upper via connecting the first magnetic tunnel junction pattern and the upper wiring;
a lower wiring disposed in the backside wiring layer;
a lower via connecting the second magnetic tunnel junction pattern and the lower wiring to each other; and
a through-contact plug penetrating the upper insulating layer, the interlayer insulating layer, and the substrate, and penetrating a portion of the backside wiring layer to connect the upper wiring and the lower wiring to each other.

4. The magnetic memory device of claim 3, wherein the second active contact extends to an interior of the upper source/drain pattern.

5. The magnetic memory device of claim 4, further comprising a lower separation structure at least partially surrounding a side surface of the second active contact,
wherein the second active contact is electrically insulated from the lower source/drain pattern by the lower separation structure.

6. The magnetic memory device of claim 4, further comprising a backside contact penetrating the backside wiring layer, the substrate, and the lower source/drain pattern and extending into the interior of the upper source/drain pattern.

7. The magnetic memory device of claim 6, further comprising a backside separation structure at least partially surrounding a side surface of the backside contact,
wherein the backside contact is electrically insulated from the lower source/drain pattern by the backside separation structure.

8. The magnetic memory device of claim 3, wherein the first active contact extends into an interior of the lower source/drain pattern.

9. The magnetic memory device of claim 8, further comprising an upper separation structure at least partially surrounding a side surface of the first active contact,
wherein the first active contact is electrically insulated from the upper source/drain pattern by the upper separation structure.

10. The magnetic memory device of claim 8, further comprising a backside contact penetrating the backside wiring layer and the substrate to extend into the interior of the lower source/drain pattern.

11. The magnetic memory device of claim 1, wherein the second active contact extends to an interior of the upper source/drain pattern,
wherein the magnetic memory device further includes a lower separation structure at least partially surrounding a side surface of the second active contact, and
wherein the second active contact is electrically insulated from the lower source/drain pattern by the lower separation structure.

12. The magnetic memory device of claim 11, further comprising:
a backside contact penetrating the backside wiring layer, the substrate, and the lower source/drain pattern to extend into the interior of the upper source/drain pattern; and
a backside separation structure at least partially surrounding a side surface of the backside contact,
wherein the backside contact is electrically insulated from the lower source/drain pattern by the backside separation structure.

13. The magnetic memory device of claim 1, wherein the first active contact extends to an interior of the lower source/drain pattern,
wherein the magnetic memory device further includes an upper separation structure at least partially surrounding a side surface of the first active contact, and
wherein the first active contact is electrically insulated from the upper source/drain pattern by the upper separation structure.

14. The magnetic memory device of claim 1, wherein the first magnetic tunnel junction pattern and the second magnetic tunnel junction pattern have different resistance characteristics.

15. A magnetic memory device comprising:
a substrate having first and second surfaces facing each other;
a first active region disposed on the first surface of the substrate, wherein the first active region includes a lower channel pattern and a lower source/drain pattern connected to the lower channel pattern;
a first interlayer insulating layer covering the lower source/drain pattern;
a first active contact extending from an upper surface of the first interlayer insulating layer into an interior of the lower source/drain pattern;
an upper insulating layer disposed on the first interlayer insulating layer;
a first magnetic tunnel junction pattern disposed in the upper insulating layer, wherein the first magnetic tunnel junction pattern is connected to the first active contact through an interlayer wiring;
a backside wiring layer disposed on the lower surface of the substrate;
a second magnetic tunnel junction pattern disposed in the backside wiring layer; and
a second active contact extending from the lower surface of the substrate into the interior of the lower source/drain pattern and being connected to the second magnetic tunnel junction pattern,
wherein each of the first and second magnetic tunnel junction patterns includes a pinned magnetic pattern, a free magnetic pattern, and a tunnel barrier pattern therebetween, and
wherein the tunnel barrier pattern of the first magnetic tunnel junction pattern is insulated-broken and has an irreversible resistance state.

16. The magnetic memory device of claim 15, further comprising a backside contact extending into the interior of the lower source/drain pattern and penetrating the backside wiring layer and the substrate.

17. The magnetic memory device of claim 15, further including:
a wiring insulating layer disposed on the upper insulating layer;
a first wiring disposed on the wiring insulating layer;
a power transmission network layer disposed on the backside wiring layer; and
a backside power wiring disposed in the power transmission network layer,
wherein the first magnetic tunnel junction pattern is connected to the first wiring through upper wiring, upper connection lines, and upper vias between the first magnetic tunnel junction pattern and the first wiring, and
wherein the second magnetic tunnel junction pattern is connected to the backside power wiring through lower wiring and lower vias between the second magnetic tunnel junction pattern and the backside power wiring.

18. The magnetic memory device of claim 15, further comprising:
a second active region stacked on the first active region and between the first interlayer insulating layer and the upper insulating layer, wherein the second active region includes an upper channel pattern and an upper source/drain pattern connected to the upper channel pattern;
a second interlayer insulating layer interposed between the first interlayer insulating layer and the upper insulating layer and covering the upper source/drain patterns, wherein the first active contact extends through the upper source/drain pattern and the second interlayer insulating layer to an upper surface of the second interlayer insulating layer; and
an upper separation structure at least partially surrounding a side surface of the first active contact,
wherein the first active contact is electrically insulated from the upper source/drain pattern by the upper separation structure.

19. A magnetic memory device comprising:
a magnetic memory device having a substrate having upper and lower surfaces facing each other, wherein the substrate includes an active pattern;
a first active region disposed on the active pattern, wherein the first active region includes a lower channel pattern and a lower source/drain pattern connected to the lower channel pattern;
a second active region stacked on the first active region, wherein the second active region includes an upper channel pattern and an upper source/drain pattern connected to the upper channel pattern;
a gate electrode disposed on the lower channel pattern and the upper channel pattern, wherein the gate electrode extends in a first direction;
an interlayer insulating layer covering the lower and upper source/drain patterns;
a first active contact extending from an upper surface of the interlayer insulating layer into an interior of the upper source/drain pattern;
an upper insulating layer disposed on the interlayer insulating layer;
a wiring insulating layer disposed on the upper insulating layer;
a first wiring disposed on the wiring insulating layer;
a first magnetic tunnel junction pattern in the upper insulating layer, wherein the first magnetic tunnel junction pattern is connected to the first active contact through interlayer wiring and upper vias, and connected to the first wiring through upper wiring and upper connection line in the wiring insulating layer;
a backside wiring layer disposed on the lower surface of the substrate;
a second magnetic tunnel junction pattern and a lower wiring disposed in the backside wiring layer, wherein the second magnetic tunnel junction pattern is disposed between the substrate and the lower wiring;
a second active contact extends from the lower surface of the substrate into the lower source/drain pattern and connected to the second magnetic tunnel junction pattern;
a lower via connecting the lower wiring and the second magnetic tunnel junction pattern to each other; and
a through-contact plug penetrating the upper insulating layer, the interlayer insulating layer, and the substrate, and penetrating a portion of the backside wiring layer to connect the upper wiring and the lower wiring to each other.

20. The magnetic memory device of claim 19, wherein each of the first and second magnetic tunnel junction patterns includes a pinned magnetic pattern, a free magnetic pattern, and a tunnel barrier pattern therebetween, and
wherein the tunnel barrier pattern of the first magnetic tunnel junction pattern is insulated-broken and has an irreversible resistance state.
